(19) United States
(12) Patent Application Publication
(10) Pub. No.: US 2025/0359363 A1
(43) Pub. Date: Nov. 20, 2025

(54) IMAGE SENSOR

(71) Applicant: SAMSUNG ELECTRONICS CO., LTD., Suwon-si (KR)

(72) Inventors: Junseok Kim, Suwon-si (KR); Seungchul Shin, Suwon-si (KR); Jaeho Lee, Suwon-si (KR); Keunjoo Park, Suwon-si (KR); Bongki Son, Suwon-si (KR)

(73) Assignee: SAMSUNG ELECTRONICS CO., LTD., Suwon-si (KR)

(21) Appl. No.: 18/937,853

(22) Filed: Nov. 5, 2024

(30) Foreign Application Priority Data
May 17, 2024 (KR) 10-2024-0064505

(51) Int. Cl. H01L 27/146; H01L 23/00

(52) U.S. Cl. CPC H10F 39/8023; H01L 24/08; H10F 39/802; H10F 39/8063; H10F 39/809; H10F 39/811; H01L 2224/08145

(57) ABSTRACT

An image sensor includes: a first region disposed in a first direction and a second direction in parallel with an upper surface of a substrate, wherein the first direction and the second direction intersect each other; a second region disposed in the first direction and the second direction; a first photodiode in the first region; a second photodiode in the second region; an image sensing pixel circuit configured to generate a first electrical signal based on charges generated by the first photodiode; an event sensing pixel circuit configured to generate a second electrical signal based on a change in an amount of charges generated by the second photodiode; and a logic circuit electrically connected to the image sensing pixel circuit, wherein the first region is disposed diagonally to the second region in a third direction, and wherein the third direction is different from the first and second directions.

### CROSS-REFERENCE TO RELATED APPLICATION

This application is based on and claims priority under 35 U.S.C. § 119 to Korean Patent Application No. 10-2024-0064505, filed on May 17, 2024, in the Korean Intellectual Property Office, the disclosure of which is incorporated by reference herein in its entirety.

### BACKGROUND

### 1. Field

The disclosure relates to an image sensor.

### 2. Description of Related Art

An image sensor is a semiconductor-based sensor configured to receive light and generate an electrical signal. The image sensor may include a pixel array having a plurality of pixels, and a circuit for driving a pixel array and generating an image. The plurality of pixels may include a photodiode configured to generate charges in response to external light and a pixel circuit configured to convert the charges generated by the photodiode into an electrical signal.

There are several types of image sensors, depending on the signal outputted by the image sensor, for example, a CMOS Image Sensor (CIS) configured to output an image signal having gray levels, and a Dynamic Vision Sensor (DVS) configured to sense a change in brightness and outputs an event signal. Conventional methods for mixing CIS and DVS pixels can introduce noise due to varying parasitic capacitance and require color reconstruction.

### SUMMARY

Provided is a hybrid image sensor having heterogeneous pixels such as CIS pixels and DVS pixels.

Provided is an image sensor for preventing fixed pattern noise from occurring in image data, effectively performing motion deblurring of the image data, and minimizing an amount of computation required for color reconstruction.

According to an aspect of the disclosure, an image sensor includes: a first region disposed in a first direction and a second direction in parallel with an upper surface of a substrate, wherein the first direction and the second direction intersect each other; a second region disposed in the first direction and the second direction; a first photodiode in the first region; a second photodiode in the second region; an image sensing pixel circuit configured to generate a first electrical signal based on charges generated by the first photodiode; an event sensing pixel circuit configured to generate a second electrical signal based on a change in an amount of charges generated by the second photodiode; and a logic circuit electrically connected to the image sensing pixel circuit, wherein the first region is disposed diagonally to the second region in a third direction, and wherein the third direction is different from the first and second directions.

According to an aspect of the disclosure, an image sensor includes: a substrate; a first photodiode in a first region in the substrate; a second photodiode in a second region in the substrate; a third photodiode in a third region in the substrate; a fourth photodiode in a fourth region in the substrate; a transfer transistor; a reset transistor; and an event sensing pixel circuit configured to generate an electrical signal based on a change in an amount of charges generated by the second photodiode, wherein the third region is disposed directly adjacent to the first region in a first direction in a plan view, wherein the fourth region is disposed directly adjacent to the first region in a second direction perpendicular to the first direction in the plan view, wherein the second region is directly disposed diagonally to the first region in a third direction different from the first and second directions in the plan view, wherein a light-receiving area of each of the first, third, and fourth photodiodes is greater than a light-receiving area of the second photodiode, and wherein the transfer transistor and the reset transistor are shared by the first photodiode.

According to an aspect of the disclosure, an image sensor includes: a substrate comprising a first surface and a second surface opposing the first surface; a first photodiode in a first region in the substrate; a second photodiode in a second region in the substrate; a first microlens on the first photodiode; a second microlens on the second photodiode; an image sensing pixel circuit configured to generate a first electrical signal based on charges generated in the first photodiode; an event sensing pixel circuit configured to generate a second electrical signal based on a change in an amount of charges generated by the second photodiode; a deep trench isolation between the first region and the second region; and a circuit electrically connected to the image sensing pixel circuit, wherein the first region is directly adjacent to the second region, wherein the deep trench isolation is in contact with the first surface of the substrate and the second surface of the substrate, and wherein a width of the first microlens in a first direction is greater than a width of the second microlens in the first direction in a plan view.

The aspects to be solved by the disclosure are not limited to the above-mentioned aspects, and other aspects not mentioned herein will be clearly understood by those skilled in the art from the following description.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a block diagram of an image sensor according to an example embodiment of the disclosure;

FIG. 2 is a plan view of pixels included in an image sensor according to an example embodiment of the disclosure;

FIGS. 3A to 3C are plan views of pixels included in an image sensor according to an example embodiment of the disclosure;

FIGS. 4 to 7 are plan views of a pixel array included in an image sensor according to an example embodiment of the disclosure;

FIGS. 8A and 8B are circuit diagrams illustrating pixel circuits of an image sensor according to an example embodiment of the disclosure;

FIG. 9 is a view illustrating a layout of an image sensor according to an example embodiment of the disclosure;

FIGS. 10 to 14 are views illustrating pixels included in an image sensor according to an example embodiment of the disclosure;

FIG. 15 is a plan view of pixels included in an image sensor according to an example embodiment of the disclosure;

FIG. 16 is a plan view of pixels included in an image sensor according to an example embodiment of the disclosure;

FIGS. 17 to 19 are plan views of pixels included in an image sensor according to an example embodiment of the disclosure;

FIG. 20 is a circuit diagram illustrating a pixel circuit of an image sensor according to an example embodiment of the disclosure;

FIGS. 21 to 23 are plan views of pixels included in an image sensor according to an example embodiment of the disclosure;

FIGS. 24 to 26 are plan views of pixels included in an image sensor according to an example embodiment of the disclosure;

FIGS. 27 to 29 are plan views of pixels included in an image sensor according to an example embodiment of the disclosure; and

FIG. 30 is a view illustrating a layout of an image sensor according to an example embodiment of the disclosure.

### DETAILED DESCRIPTION

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples of the embodiments, are intended to encompass equivalents the embodiments.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations of A, B, and C. As an additional example, the expression “at least one of a, b, or c” may indicate only a, only b, only c, both a and b, both a and c, both b and c, all of a, b, and c, or variations of a, b, and c. Similarly, the term “set” means one or more. Accordingly, the set of items may be a single item or a collection of two or more items.

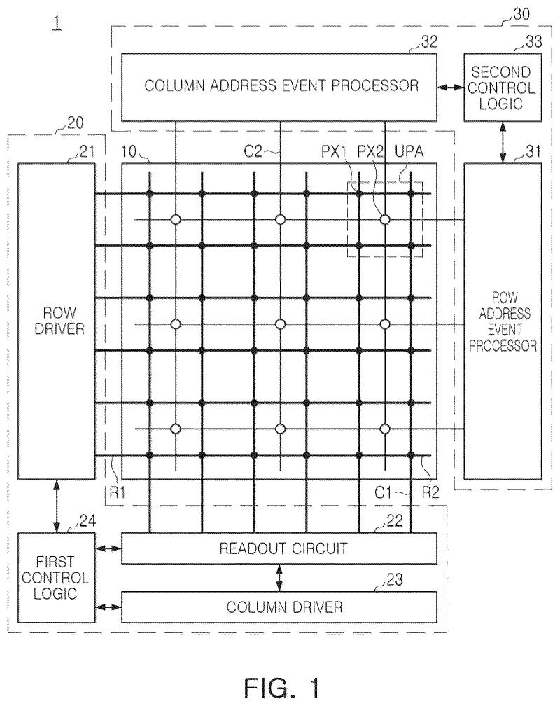

FIG. 1 is a block diagram of an image sensor according to an example embodiment of the disclosure.

Referring to FIG. 1, an image sensor 1 according to an example embodiment of the disclosure may include a pixel array 10, a first logic circuit 20, and a second logic circuit 30.

The pixel array 10 may include unit pixel arrays UPA arranged in an array shape along a plurality of rows and a plurality of columns. Each of the unit pixel arrays UPA may include a plurality of image sensing pixels PX1 and one or more event sensing pixels PX2. For example, the UPA shown in FIG. 1 includes four image sensing pixels (black dots) and one event sensing pixel (white dot).

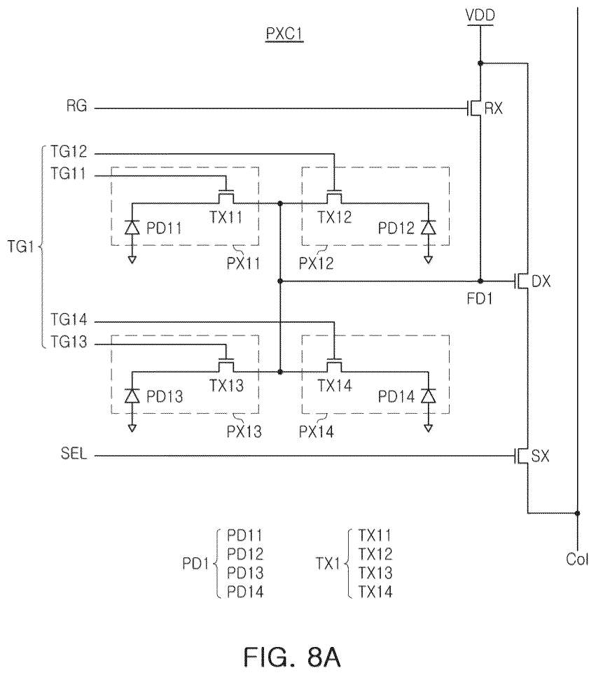

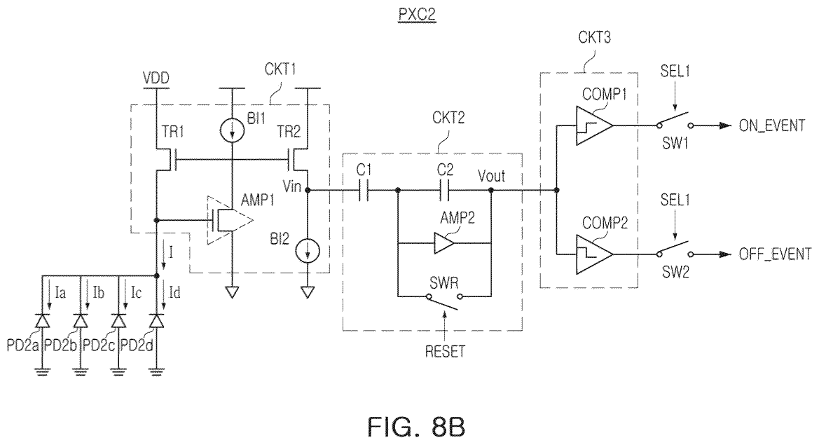

The image sensing pixel PX1 may include at least one ‘photoelectric conversion element’ and a first pixel circuit including a transfer transistor, a driving transistor, a selection transistor, and a reset transistor. In an example embodiment, a plurality of image sensing pixels in each of the UPA may share at least a portion of the first pixel circuit. The event sensing pixel PX2 may include at least one ‘photoelectric conversion element’ and a second pixel circuit including a CKT1, CKT2, and CKT3 in FIG. 8B.

According to an example embodiment of the disclosure, the image sensing pixel PX1 and the event sensing pixel PX2 may be heterogeneous pixels that output different types of electrical signals. For example, the image sensing pixel may be a CMOS Image Sensor (CIS) pixel outputting an image signal having a gray level indicating the degree of brightness of light in a predetermined wavelength range. In some embodiments, the event sensing pixel PX2 may be a Dynamic Vision Sensor (DVS) sensing a change in light brightness and outputting an event signal indicating whether the light has become brighter or darker.

The CIS pixel outputs the image signal including gray level information that corresponds to a plurality of bits of data. In some embodiments, since each of the CIS pixels included in the pixel array 10 is able to generate and output an image signal in one frame period, the frame period of the CIS pixels may be relatively long.

On the other hand, the event signal output by the DVS pixel may include information on whether there is a change in light brightness and information on a direction of the change in light brightness, and may include relatively few bits of data, such as one or two bits. In some embodiments, among the DVS pixels included in the pixel array 10, only pixels in which the change in light brightness is sensed may generate and output an event signal, and thus, the frame period of DVS pixels may be relatively short.

When an object moves between the frame cycles of the CIS pixels, afterimages referred to as ‘motion blur’ may occur in an image generated from an image signal acquired from the CIS pixels. Since the DVS pixels have a shorter frame period than that of the CIS pixels, the DVS pixels may event signals corresponding to positions in which changes in light brightness occur between the frame periods of the CIS pixels. When the CIS pixels and the DVS pixels are mixed in the pixel array 10, and the image signals obtained from the CIS pixels may be corrected using the event signals obtained from the DVS pixels, motion deblurring, an operation to remove motion blur, may be easily performed.

In the related art, when a pixel array having a mixture of the CIS pixels and the DVS pixels is configured by replacing some of the plurality of CIS pixels connected to row lines and column lines with the DVS pixels, the quality of image signals obtained from the pixel array may deteriorate.

In the related art, depending on whether the DVS pixel is connected to the row lines and the column lines, parasitic capacitance may vary between the row lines and the column lines. When the parasitic capacitance varies between the row lines and the column lines, a difference may occur in the settling time of the CIS pixels. Image signals generated from pixels having different settling time may cause noise in fixed positions in the image. The noise may be referred to as fixed pattern noise.

In the related art, gray level information, that is, color information, according to a wavelength range may not be generated in positions replaced by the DVS pixels. Accordingly, in order to generate the image, a color reconstruction operation may be required to estimate a color of a position in which color information is lost.

According to an example embodiment of the disclosure, the pixel array 10 may include a plurality of image sensing pixel PX1 connected to first row lines R1 and first column lines C1, and a plurality of event sensing pixels PX2 connected to second row lines R2 and second column lines C2.

The plurality of image sensing pixel PX1 may be arranged at uniform intervals (or at substantially uniform intervals) based on the first row lines R1 and the first column lines C1. In some embodiments, the plurality of event sensing pixels PX2 may be arranged at uniform intervals (or at substantially uniform intervals) between the plurality of image sensing pixel PX1 based on the second row lines R2 and the second column lines C2. For example, each of the plurality of event sensing pixels PX2 may be adjacent to at least one image sensing pixel group PG1.

According to an example embodiment of the disclosure, since the event sensing pixels PX2 may be between the image sensing pixels PX1, the motion deblurring of the image obtained from the image sensing pixels PX1 may be effectively performed using the event signals obtained from the event sensing pixels PX2.

In some embodiments, although the pixel array 10 includes image sensing pixels PX1 and event sensing pixels PX2, the image sensing pixels PX1 may be evenly (or substantially evenly) distributed in the pixel array 10. Accordingly, color loss in the image data obtained from the image sensing pixel PX1 may be minimized, and the amount of computation required for color reconstruction may be minimized.

In some embodiments, pixels of the same type may be connected to the first row lines R1 and the first column lines C1. Since the parasitic capacitance of the first row lines R1 and the parasitic capacitance of the first column lines C1 may be made uniform (or substantially uniform), respectively, the settling time of the image sensing pixel PX1 may become uniform (or substantially uniform). Accordingly, fixed pattern noise in the image obtained from the image sensing pixel PX1 may be alleviated.

The first logic circuit 20 may include circuits for controlling the image sensing pixels PX1 of the pixel array 10. For example, the first logic circuit 20 may include a row driver 21, a readout circuit 22, a column driver 23, and a first control logic 24.

The row driver 21 may drive the image sensing pixels PX1 in row units. For example, the row driver 21 may generate a transmission control signal for controlling the transfer transistor of the first pixel circuit, a reset control signal for controlling the reset transistor, and a selection control signal for controlling the selection transistor, and may input the generated signals to the pixel array 10 in row units. For example, the control signal generated by the row driver 21 may be input to one of the first row lines R1.

The readout circuit 22 may include a correlated double sampler (CDS) and an analog-to-digital converter (ADC). The correlated double samplers may be connected to the image sensing pixels PX1 through the column lines C1. The correlated double samplers may perform correlated double sampling by receiving the image signal from the image sensing pixels PX1 connected to the row line selected by a row line selection signal of the row driver 21. Image signals may be received through the column lines C1. The analog-to-digital converter may convert the image signal detected by the correlated double sampler into a digital image signal and transfer the digital image signal to the column driver 23.

The column driver 23 may include a latch or a buffer circuit capable of temporarily storing a digital image signal, and an amplification circuit, and may process digital image signals received from the readout circuit 22. The row driver 21, the readout circuit 22, and the column driver 23 may be controlled by the first control logic 24. The first control logic 24 may include a timing controller for controlling an operation timing of the row driver 21, the readout circuit 22, and the column driver 23.

Image sensing pixels PX1 in the same position in a vertical direction may share the same first column line C1. For example, image pixels PX1 in the same position in the vertical direction may be sequentially selected by the row driver 21 and may output the image signals through the first column lines C1.

The second logic circuit 30 may include circuits for controlling the event sensing pixels PX2 of the pixel array 10. For example, the second logic circuit 30 may include a row address event processor 31, a column address event processor 32, and a second control logic 33.

The second control logic 33 may transfer a first selection signal for selecting one of the plurality of second column lines C2 to the column address event processor 32. In response to (or based on) the first selection signal, the event sensing pixels PX2 connected to the selected second column line C2 may be turned on at the same time.

The second control logic 33 may transfer a second selection signal to the row address event processor 31. In response to the second selection signal, the row address event processor 31 may be connected to at least one of a plurality of second row lines R2. For example, the row address event processor 31 may obtain an event signal from at least portions of the plurality of event sensing pixels PX2 connected to the selected second low line R2, in response to the second selection signal.

At least portions of the event sensing pixels PX2 simultaneously (or substantially simultaneously) turned on in response to the first selection signal may output an on-event signal or an off-event signal to the row address event processor 31. For example, a pixel in which a change in light brightness of the pixel is higher than a reference value in a positive direction, among the event sensing pixels PX2, may output the on-event signal, and a pixel in which a change in light brightness of the pixel is higher than the reference value in a negative direction, among the event sensing pixels PX2, may output an off-event signal. A pixel in which a change in light brightness of the pixel is lower than the reference value, among the event sensing pixels PX2, may not output the on-event signal and the off-event signal.

The row address event processor 31 may include handshaking logics corresponding to the plurality of second row lines R2. The handshaking logics may obtain event signals from the event sensing pixels PX2 connected to the selected second column line C2, and may transfer a reset signal to the event sensing pixels PX2 in response to the event signals.

The second control logic 33 may receive the event signal from the row address event processor 31, and may provide a reset signal for resetting the row address event processor 31 to the row address event processor 31.

In an example of FIG. 1, a case in which the image sensing pixels PX1 are CIS pixels and the event sensing pixel PX2 are a DVS pixels has been described as an example, the disclosure is not limited thereto. The event sensing pixels may be included in a Time of Flight (ToF) sensor.

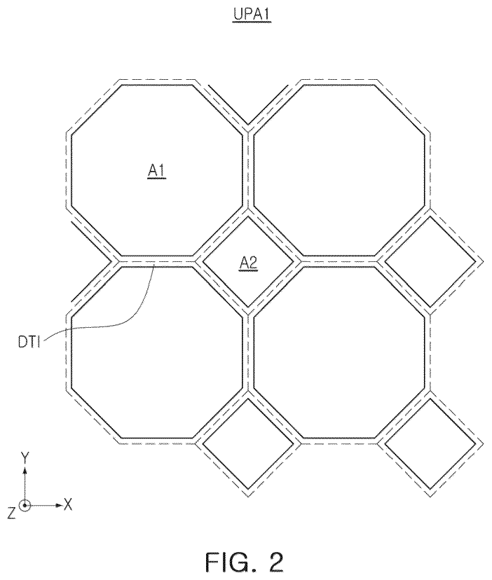

Hereinafter, referring to FIGS. 2 to 30, an image sensor according to an example embodiment of the disclosure will be described in detail.

FIG. 2 is a plan view of pixels included in an image sensor according to an example embodiment of the disclosure.

According to an example embodiment of the disclosure, a unit pixel array UPA1 may include a plurality of first regions A1 and a plurality of second regions A2. The plurality of first regions A1 may be in the first direction (X-direction) and a second direction (Y-direction) in parallel with an upper surface of a substrate and intersecting each other. In some embodiments, the plurality of second regions A2 may also be in the first direction (X-direction) and the second direction (Y-direction).

In an example embodiment, each of the plurality of first regions A1 may have an octagonal shape including two first edges extending in the first direction (X-direction), two second edges extending in the second direction (Y-direction), and four third edges. Each of the plurality of first regions A1 may be adjacent to at least one first region A1 in at least one of the first edges and at least one of the second edges.

Each of the plurality of second regions A2 may have a rectangular shape. The plurality of second regions A2 may be disposed between the plurality of first regions A1. For example, the plurality of second regions A1 may be adjacent to at least one second region A2 in at least one of the third edges.

In some embodiments, a deep trench isolation (DTI) may be formed in boundaries between the plurality of first regions A1 and the plurality of second regions A2. The DTI may prevent cross-talk between regions. The DTI may include an insulating material such as oxide, and a sidewall of the DTI may be formed of a material having high reflectivity.

At least one photodiode of the image sensing pixel described with reference to FIG. 1 may be in each of the plurality of first regions A1, and at least one photodiode of the event sensing pixel described with reference to FIG. 1 may be in each of the plurality of second regions A2. In an example embodiment, a size of the first region A1 may be larger than a size of the second region A2. In some embodiments, a sum of light-receiving areas of the photodiodes in the first regions A1 may be larger than a sum of the light-receiving areas of the photodiodes in the second regions A2.

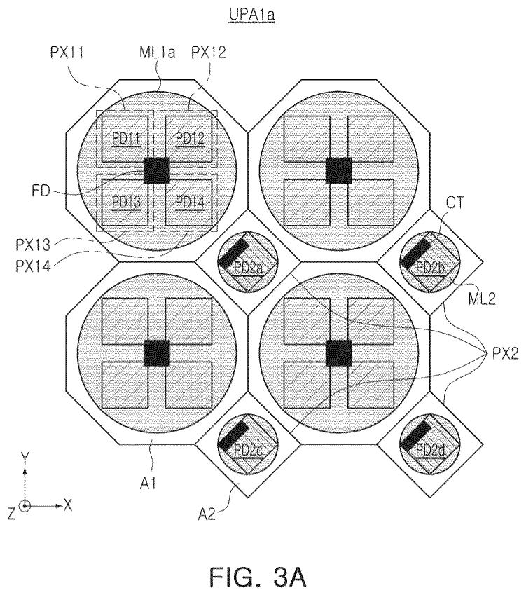

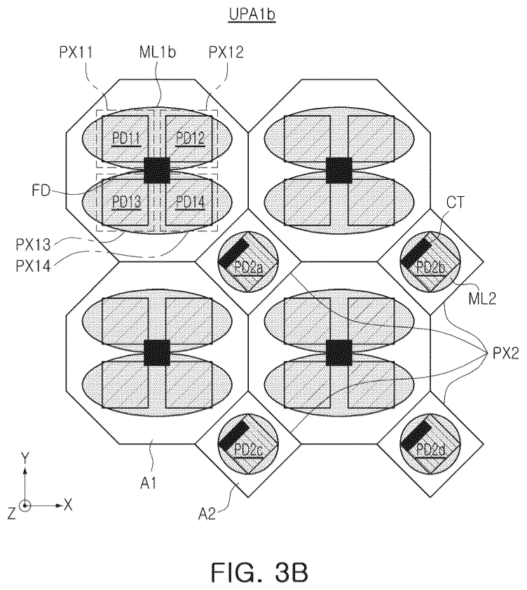

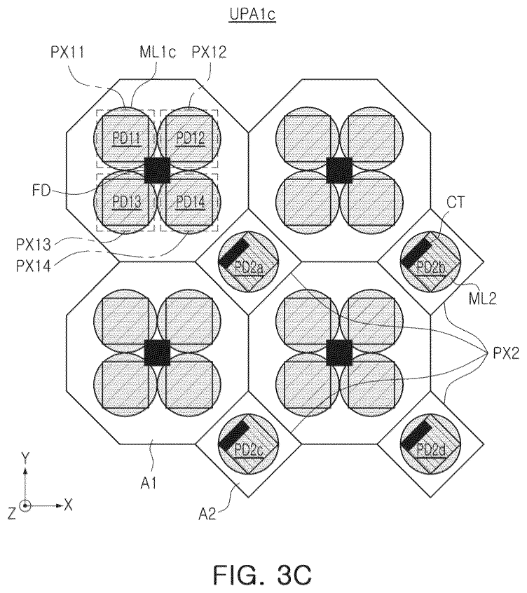

FIGS. 3A to 3C are plan views of pixels included in an image sensor according to an example embodiment of the disclosure.

Referring to FIGS. 3A to 3C, unit pixel arrays UPA1a, UPA1b and UPA1c, respectively, may include a plurality of image sensing pixels PX1 and one or more event sensing pixels PX2. The unit pixel arrays UPA1a, UPA1b and UPA1c may correspond to the unit pixel array UPA1 described with reference to FIG. 2.

Each of first regions A1 may include one or more photodiodes. In the examples of FIGS. 3A to 3C, each of the first regions A1 may include four photodiodes PD11 to PD14 arranged in a 2×2 shape in the first direction (X-direction) and the second direction (Y-direction). Each of the four photodiodes PD11 to PD14 are belonging to a corresponding four image sensing pixels PX11 to PX14 and the four image sensing pixels may share one floating diffusion node FD.

Each of second regions A2 may include one or more photodiodes. In examples of FIGS. 3A to 3C, each of the second regions A2 may include one photodiode PD2a, PD2b, PD2c, and PD2d. In an example embodiment, each of PD2a, PD2b, PD2c, and PD2d in the unit pixel arrays UPA1a, UPA1b and UPA1c may be included in one event sensing pixel PX2.

Each of the photodiode PD2a, PD2b, PD2c, and PD2d may convert light incident through the microlens in the upper portion into charges. A current having a magnitude corresponding to the amount of charges generated in Each of the photodiode PD2a, PD2b, PD2c, and PD2d may flow to the second pixel circuit of the event sensing pixel PX2 through a contact CT connected to each of the second photodiodes PD2. The event sensing pixel PX2 may generate an event signal based on the amount of currents flowing through the contacts CT.

In the unit pixel array UPA1, microlenses in upper portions of the first region A1 and the second region A2 may have various sizes and shapes.

In the example of FIG. 3A, the first region A1 may include one microlens ML1a in upper portions of the four photodiodes PD11 to PD14. For example, a center point of the first microlens ML1a may overlap the floating diffusion node FD in a vertical direction (Z-direction), perpendicular to an upper surface of the substrate. In some embodiments, the second region A2 may include one microlens ML2 in an upper portion of one second photodiode.

However, the disclosure is not limited thereto. As another example, each of image sensing pixels PX11 to PX14 has one microlens in the first region A1.

In the example of FIG. 3B, the first region A1 may include two second microlenses ML1b. Each of the two second microlenses ML2b may be disposed on upper portions of the two photodiodes PD11 and PD12 and upper portions of the two photodiodes PD13 and PD14. In some embodiments, the second region A2 may include one second microlens ML2 disposed on the upper portion of one photodiode.

In the example of FIG. 3C, the first region A1 may include four first microlenses ML1a in upper portions of each of the four photodiodes PD11 to PD14. In some embodiments, the second region A2 may include one second microlens ML2 in the upper portion of one photodiode.

Unit pixel arrays, such as the unit pixel array UPA1 described with reference to FIGS. 2, 3A, 3B and 3C may be included in the pixel array 10 as described with reference to FIG. 1 by being disposed in the first direction (X-direction) and the second direction (Y-direction).

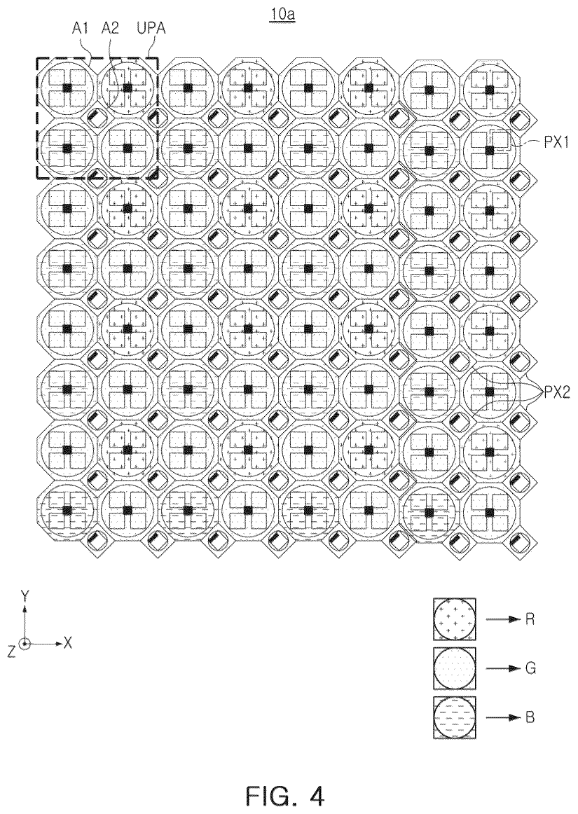

FIGS. 4 to 7 are plan views of a pixel array included in an image sensor according to an example embodiment of the disclosure.

Referring to FIG. 4, a plurality of unit pixel arrays UPA may be in the first direction (X-direction) and the second direction (Y-direction), and thus, may be included in a pixel array 10a. In the example of FIG. 4, the unit pixel array UPA is illustrated as having the same shape as the unit pixel array UPA1a described with reference to FIG. 3A, but the shape of the unit pixel array UPA is not limited to the shape of the unit pixel array UPA1a.

The unit pixel array UPA may include a plurality of first regions A1 and a plurality of second regions A2. In FIG. 4, image sensing pixels PX1 in the first region A1 and a event sensing pixel PX2 including four second regions A2 are displayed as an example.

The unit pixel array UPA may include color filters that may receive light passing through the microlens, and may transmit light corresponding to a certain range of wavelengths among the received light. For example, each of the color filters may transmit light corresponding to a wavelength of a single color among the received light, for example, one of red (R), green (G), and blue (B).

In the example of FIG. 4, the color filter may be included in the first regions A1 of the unit pixel array UPA, and the color filter may not be included in the second regions A2. For example, the second region A2 may transmit light of at least all wavelengths in a visible light band, and the second photodiode PD2 may generate charges based on light of all wavelengths in at least the visible light band.

In the first regions A1, color filters may be in a tetra pattern. The tetra pattern may refer to a color pattern in which a pixel group including four pixels arranged in a 2×2 shape includes a color filter that transmit light of the same wavelength.

For example, in the first regions A1 arranged in a 2×2 shape in the unit pixel array UPA, a red filter, a green filter, and a blue filter may be arranged in a Bayer pattern. In some embodiments, each of the color filters may be shared by four image sensing pixels PX1 included in the first regions A1.

However, the disclosure is not limited thereto. As a first example, the first regions A1 may include only one single color filter among the red filter, the green filter, and the blue filter. As a second example, the first regions A1 may include different color filters that transmit light of different colors, such as cyan, magenta, or yellow. As a third example, at least portions of the first regions A1 may not include the color filter.

The first regions A1 in an intermediate portion, excluding the first regions A1 in edges in the pixel array 10a, (that is, excluding the edges of the first regions A1 in the pixel array 10a) may be adjacent to four first regions A1 in the first direction (X-direction) and the second direction (Y-direction). In some embodiments, the first regions A1 in the intermediate portion may be adjacent to four second regions A2 in a third direction and a fourth direction in parallel with the upper surface of the substrate and intersecting the first direction (X-direction) and the second direction (Y-direction). The second regions A2 in an intermediate portion, excluding the edges of the second regions A2, may be adjacent to the four first regions A1.

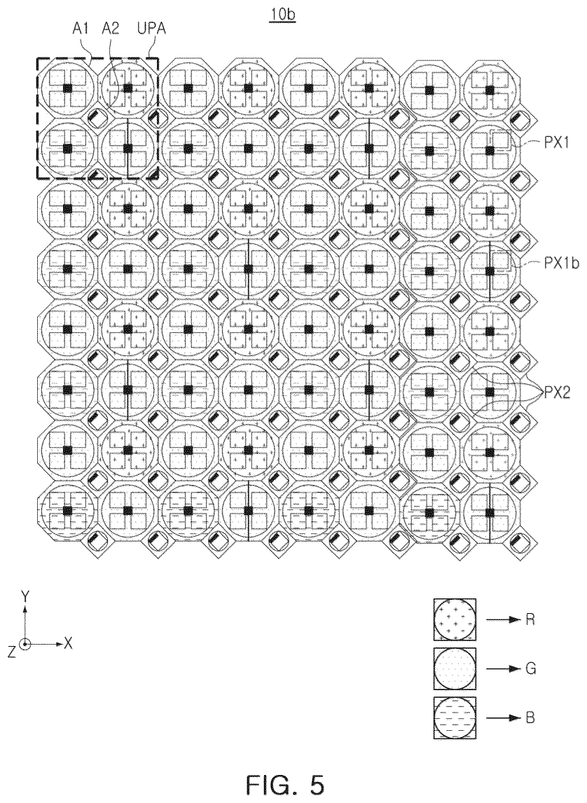

Referring to FIG. 5, a plurality of unit pixel arrays UPA may be in the first direction (X-direction) and the second direction (Y-direction), and thus, may be included in a pixel array 10b. The pixel array 10b of FIG. 5 may have a similar structure to the pixel array 10a of FIG. 4. However, in the pixel array 10b of FIG. 5, portions of the image sensing pixels among the plurality of image sensing pixels PX1 may be phase detection pixels PX1b.

In the example of FIG. 5, each of the phase detection pixels PX1b may include two photodiodes having a first relative position in the first direction (X-direction), and two photodiodes having a second relative position different from the first relative position in the first direction (X-direction). Each of the phase detection pixels PX1b may detect a phase difference in the first direction (X-direction) based on the amount of charges accumulated in the photodiodes having the first relative position and the amount of charges accumulated in the photodiodes having the second relative position, and may provide autofocus functionality. However, the disclosure is not limited thereto, and the phase detection pixels PX1b may be pixels detecting a phase difference in the second direction (Y-direction).

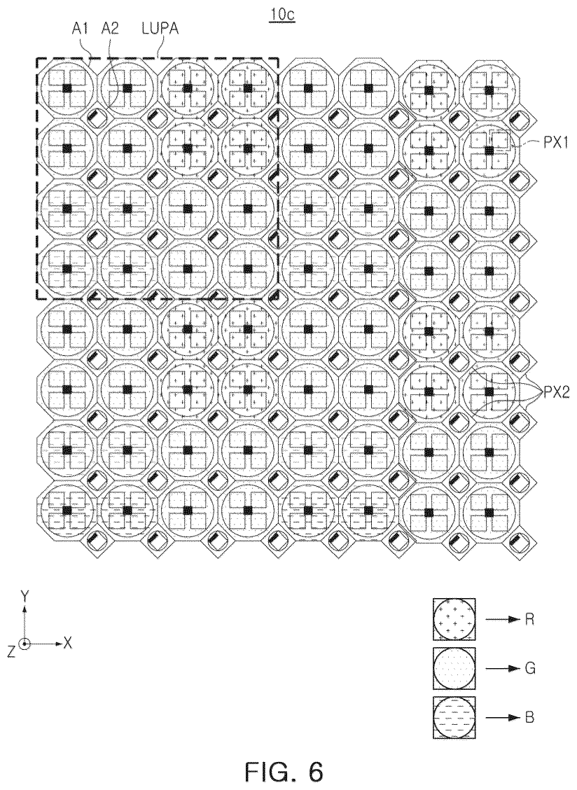

Referring to FIG. 6, a plurality of large unit pixel arrays LUPA may be in the first direction (X-direction) and the second direction (Y-direction), and thus, may be included in a pixel array 10c. The pixel array 10c of FIG. 6 may have a similar structure to the pixel array 10a of FIG. 4. However, a pattern of color filters in the pixel array 10c of FIG. 6 may be different from a pattern of color filters in the pixel array 10a in FIG. 4.

For example, the large unit pixel array LUPA illustrated in FIG. 6 may have a structure in which the unit pixel arrays UPA illustrated in FIG. 4 are arranged in the 2×2 shape in the first direction (X-direction) and the second direction (Y-direction). In the large unit pixel array LUPA of FIG. 6, the color filters may be arranged in a hexadeca pattern. For example, in the plurality of first regions A1 arranged in a 4×4 shape included in the large unit pixel array LUPA, a green filter, a red filter, and a blue filter may be arranged in a Bayer pattern in units of the four first regions A1 arranged in the 2×2 shape.

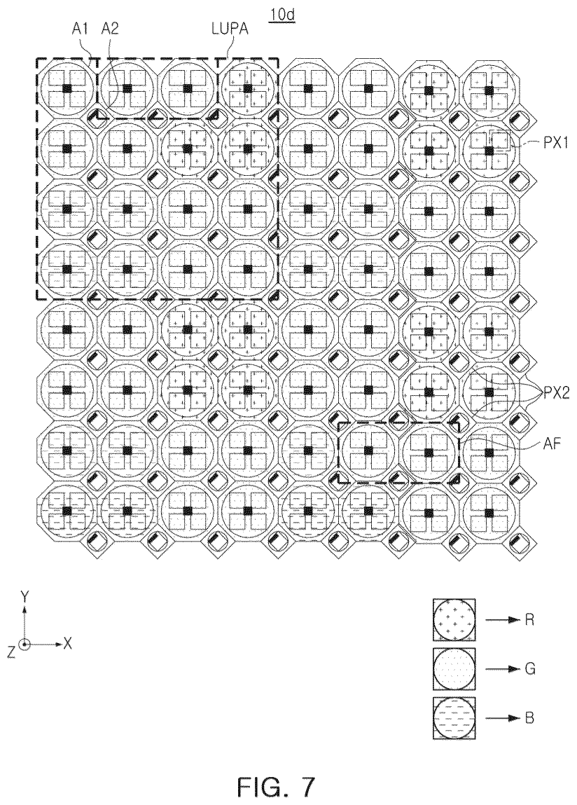

Referring to FIG. 7, a plurality of large unit pixel arrays LUPA may be in the first direction (X-direction) and the second direction (Y-direction), and thus, may be included in the pixel array 10d. The pixel array 10d of FIG. 7 may have a structure similar to that of the pixel array 10c of FIG. 6. However, a pattern of the color filters arranged in the pixel array 10d of FIG. 7 may be different from a pattern of the color filters arranged in the pixel array 10c of FIG. 6.

For example, some of the image sensing pixels PX1 of the pixel array 10d may provide an autofocus function (AF). The image sensing pixels PX1 providing the autofocus function (AF) may include a color filter for transmitting the same color. For example, eight image sensing pixels PX1 included in two first regions A1 adjoining each other in the first direction (X-direction) including color filters for transmitting the same color may detect the phase difference in the first direction (X-direction) and provide the autofocus function in the first direction (X-direction). However, the disclosure is not limited thereto. For example, the pixel array 10d may also include image sensing pixels PX1 included in two first regions A1 adjoining each other in the second direction (Y-direction) and providing the autofocus function in the second direction (Y-direction).

As described with reference to FIG. 1, the image sensing pixels PX1 including the photodiodes in the first regions A1 of the pixel arrays 10a, 10b, 10c and 10d may be CIS pixels, and the event sensing pixels PX2 including the second photodiodes in the second regions A2 may be DVS pixels.

FIGS. 8A and 8B are circuit diagrams illustrating the first pixel circuit and the second pixel circuit, respectively, of an image sensor according to an example embodiment of the disclosure.

FIG. 8A illustrate a circuit diagram of a first pixel circuit PXC1.

Referring to FIG. 8A, a first pixel circuit PXC1 of the image sensing pixels PX11, PX12, PX13 and PX14 may output an electrical signal using charges generated by a plurality of photodiodes PD11, PD12, PD13 and PD14 (PD1). An operation of active elements included in the image sensing pixel circuit may be controlled by the first logic circuit 20 included in the image sensor 1 described with reference to FIG. 1.

The first pixel circuit PXC1 may include a reset transistor RX, a plurality of first transfer transistors TX11, TX12, TX13 and TX14 (TX1), a driving transistor DX and, a selection transistor SX. The plurality of image sensing pixels PX11 to PX14 may include a dedicated photodiode PD1 and a dedicated first transfer transistor TX1. In some embodiments, the plurality of image sensing pixels PX1 may share the reset transistor RX, the driving transistor DX, and the selection transistor SX.

Each of the plurality of photodiodes PD1 may be connected to a first floating diffusion node FD1 through the plurality of first transfer transistors TX1. The plurality of photodiodes PD1 may share the first floating diffusion node FD1.

Each of the plurality of first transfer transistors TX1 may transfer charges accumulated in each of the plurality of photodiodes PD1 to the first floating diffusion node FD1 based on a plurality of first transmission control signals TG11, TG12, TG13 and TG14 (TG1) transmitted from a row driver. The plurality of photodiodes PD1 may generate electrons as main charge carriers. The driving transistor DX may operate as a source follower buffer amplifier by the charge accumulated in the first floating diffusion node FD1. The driving transistor DX may amplify the charges accumulated in the first floating diffusion node FD1 and transfer the charges to the selection transistor SX.

The reset transistor RX may reset a voltage of the first floating diffusion node FD1 to a reset voltage based on a reset control signal RG transmitted from the row driver.

The selection transistor SX may operate by the selection control signal SEL input by the row driver, and may perform switching and addressing operations. When the selection control signal SEL is applied from the row driver, a voltage may be output to a column line Col connected to the selection transistor SX. The voltage may be detected by a column driver and a readout circuit connected to the column line Col. The column driver and the readout circuit may detect the reset voltage in a state in which no charge is accumulated in the first floating diffusion node FD1, and may detect a pixel voltage in a state in which charges are accumulated in the first floating diffusion node FD1. In an example embodiment, the image sensor may generate an image signal by calculating a difference between the reset voltage and the pixel voltage.

FIG. 8B illustrates a circuit diagram of the event sensing pixel PX2.

Referring to FIG. 8B, a second pixel circuit PXC2 of the event sensing pixel PX2 may output an electrical signal using charges generated by a plurality of photodiodes PD2a to PD2d. An operation of active elements included in the second pixel circuit PXC2 may be controlled by a second logic circuit 30 included in the image sensor 1 described with reference to FIG. 1.

The second pixel circuit PXC2 includes a conversion circuit CKT1, an amplification circuit CKT2, a comparison circuit CKT3, a first switch SW1, and a second switch SW2. The plurality of photodiodes PD2a to PD2d may generate charges in response to light, and currents Ia, Ib, Ic and Id may flow to the plurality of photodiodes PD2 depending on the amount of the generated charges.

The plurality of photodiodes PD2a to PD2d may be connected to a common node. A current I corresponding to the sum of charges generated by the plurality of photodiodes PD2a to PD2d may be input to the conversion circuit CKT1.

The conversion circuit CKT1 may sense the current I flowing due to the charges generated by the photodiodes PD2a to PD2d, and may output a first voltage Vin corresponding to the current I. The conversion circuit CKT1 may include a first transistor TR1, a second transistor TR2, a first amplifier AMP1, a first bias circuit BI1 and a second bias circuit BI2. The first amplifier AMP1, the first bias circuit BI1, and the second bias circuit BI2 may be implemented with transistors.

The first transistor TR1 may be connected in series to the plurality of photodiodes PD2 connected in parallel. The first bias circuit BI1 and the first amplifier AMP1 may be connected in series. In some embodiments, a gate of the first transistor TR1 may be connected between a gate of the second transistor TR2 and the first bias circuit BI1, and the first amplifier AMP1.

The second transistor TR2 may be connected in series with the second bias circuit BI2. The second transistor TR2 may operate as a source follower. The second transistor TR2 may output a first voltage Vin corresponding to a magnitude of the current I.

The amplifier circuit CKT2 may include a first capacitor C1, a second capacitor C2, a second amplifier AMP2, and a reset switch SWR. The reset switch SWR may be turned on in response to a reset control signal RESET received from a row address event processor, and may reset a second voltage Vout output by the amplifier circuit CKT2. Through the reset operation described above, the second voltage Vout may be reset to a constant voltage.

The amplifier circuit CKT2 may output the second voltage Vout associated with a change in the first voltage Vin over time based on the first voltage Vin. In other words, the amplifier circuit CKT2 may amplify the first voltage Vin and may output the second voltage Vout so as to display a change in light intensity

The comparison circuit CKT3 may include a first comparator COMP1 and a second comparator COMP2. The comparison circuit CKT3 may output an on-event signal ON_EVENT or an off-event signal OFF_EVENT through a change in the second voltage Vout. For example, the first comparator COMP1 may compare the second voltage Vout with an on-threshold voltage, and may generate the on-event signal ON_EVENT according to a comparison result. The second comparator COMP2 may compare the second voltage Vout with an off-threshold voltage, and may generate the off-event signal OFF_EVENT according to the comparison result.

The comparison circuit CKT3 may generate an on-event signal ON_EVENT or an off-event signal OFF_EVENT when a change in intensity of light incident on the photodiodes PD2 is greater than a certain standard range. For example, the on-event signal ON_EVENT may have a high logic value when brightness of light incident on the photodiodes PD2 increases by a level greater than or equal to the standard range. The off-event signal OFF_EVENT may have a high logic value when the brightness of light incident on the photodiodes PD2 decreases by the level greater than or equal to the standard range.

The second pixel circuit PXC2 may receive a first selection signal SEL1 from a digital address event processor through a column address event processor. The first switch SW1 and the second switch SW2 may be turned on in response to the first selection signal SEL1. When the first switch SW1 and the second switch SW2 are turned on, the generated on-event signal ON_EVENT or the generated off-event signal OFF_EVENT may be output to the row address event processor.

For example, when the brightness of light incident on the photodiodes PD2 increases by the level greater than or equal to the standard range, the second pixel circuit PXC2 may output the on-event signal ON_EVENT to the row address event processor through the first switch SW1 turned on in response to the first selection signal SEL1. When the brightness of light incident on the photodiodes PD2 decreases by the level greater than or equal to the standard range, the second pixel circuit PXC2 may output the off-event signal OFF_EVENT to the row address event processor through the second switch SW2 turned on in response to a second selection signal SEL2. When the change in brightness of light incident on the photodiodes PD2 is smaller than a level of the standard range, the second pixel circuit PXC2 may not output the on-event signal ON_EVENT and the off-event signal OFF_EVENT.

After the comparison circuit CKT3 outputs the on-event signal ON_EVENT or the off-event signal OFF_EVENT, the amplifier circuit CKT2 may receive a reset signal RESET from the row address event processor. The second voltage Vout output from the amplifier circuit CKT2 may be reset by the reset signal RESET.

In an example embodiment, a second pixel circuit PXC2 may occupy a larger area on the substrate than a first pixel circuit PXC1. In examples of FIGS. 8A and 8B, the first pixel circuit PXC1 may include only seven transistor elements, but the second pixel circuit PXC2 may include circuits having a relatively complex structure, such as a comparator circuit. According to an example embodiment of the disclosure, in the image sensor, the first pixel circuit PXC1 and the second pixel circuit PXC2 may be vertically stacked, and the first pixel circuit PXC1 and the second pixel circuit PXC2 may be arranged effectively.

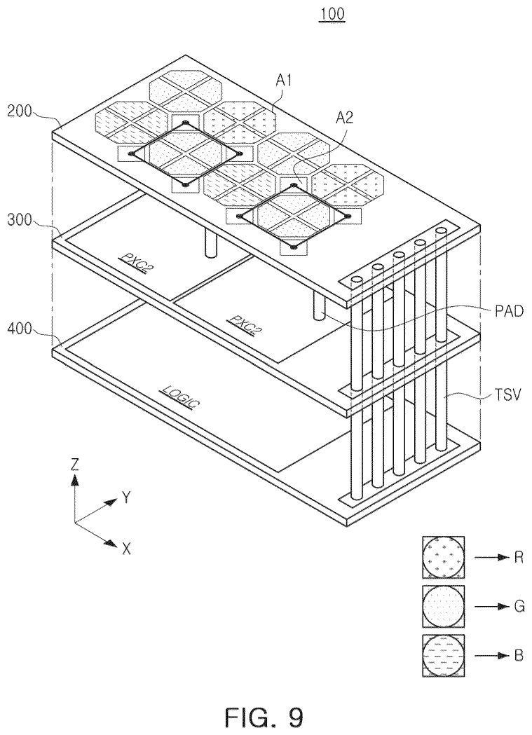

FIG. 9 is a view illustrating a layout of an image sensor according to an example embodiment of the disclosure.

Referring to FIG. 9, an image sensor 100 may include an upper semiconductor chip 200, an intermediate semiconductor chip 300, and a lower semiconductor chip 400. Each of the upper semiconductor chip 200, the intermediate semiconductor chip 300 and the lower semiconductor chip 400 may include a main region and a peripheral region.

For example, photodiodes PD1 and photodiodes PD2 may be arranged in the main region of the upper semiconductor chip 200. FIG. 9 illustrates first regions A1 in which the photodiodes PD1 may be arranged, and second regions A2 in which the photodiodes PD2 may be arranged.

According to an example embodiment of the disclosure, the upper semiconductor chip 200 may further include image sensing pixel circuits formed in a lower portion of the first photodiodes PD1. For example, one first region A1 of the upper semiconductor chip 200 may include four photodiodes PD1 included in the image sensing pixels and a first pixel circuit. The first pixel circuit may correspond to that described with reference to FIG. 8A.

According to an example embodiment of the disclosure, second pixel circuits PXC2 may be arranged in the main region of the intermediate semiconductor chip 300. Four photodiodes PD2 of the upper semiconductor chip 200 and the second pixel circuit PXC2 of the intermediate semiconductor chip 300 may be electrically connected through a signal pad PAD or a metal to metal connection such as a copper to copper hybrid bonding.

In the example of FIG. 9, the second pixel circuit PXC2 may occupy a region corresponding to four first regions A1 and four second regions A2. In some embodiments, the photodiodes PD2 in the four second regions A2 may be connected to one second pixel circuit PXC2 through the signal pad PAD or the copper to copper hybrid bonding. For example, the four photodiodes PD2 may be electrically connected through interconnection patterns in the upper semiconductor chip 200, and the four photodiodes PD2 may be connected to the second pixel circuit PXC2 through one signal pad PAD.

According to an example embodiment of the disclosure, since the second pixel circuit PXC2 are disposed on the intermediate semiconductor chip 300, even when an area occupied by one second pixel circuit PXC2 is larger than a size of the second region A2 in which the photodiode PD2 is disposed, an area of the image sensor 100 in an X-Y plane may not increase.

In some embodiments, by configuring one event sensing pixel using four photodiodes PD2, even when an area occupied by one second pixel circuit PXC2 is larger than a size of the first region A1 in which the image sensing pixels PX1 is disposed, an area of the image sensor 100 in the X-Y plane may not increase.

The main region of the lower semiconductor chip 400 may include a logic circuit LOGIC for the image sensing pixels PX1 and the event sensing pixels PX2. For example, the logic circuit LOGIC may include the first logic circuit 20 and the second logic circuit 30 described with reference to FIG. 1. In an example embodiment, the logic circuit LOGIC may further include an Image Signal Processor (ISP) generating images by processing image signals, and an Event Signal Processor (ESP) processing event signals.

Peripheral circuits connected to circuits of main regions may be in the peripheral regions of each of the upper semiconductor chip 200, the intermediate semiconductor chip 300 and the lower semiconductor chip 400.

The image sensor 100 may include through-vias (TSV) that penetrate through the peripheral regions. For example, FIG. 9 illustrates the through-vias (TSV) connecting peripheral circuits of the upper semiconductor chip 200, the intermediate semiconductor chip 300 and the lower semiconductor chip 400 to each other.

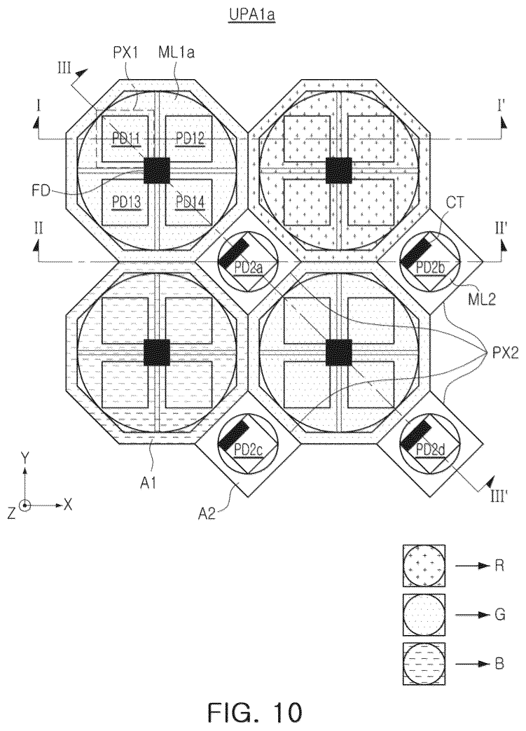

Hereinafter, the structure of an image sensor according to an example embodiment of the disclosure will be described in detail with reference to FIGS. 10 to 14.

FIGS. 10 to 14 are views illustrating pixels included in an image sensor according to an example embodiment of the disclosure.

FIG. 10 illustrates pixels included in a unit pixel array UPA1a. The unit pixel array UPA1a of FIG. 10 may correspond to the unit pixel array UPA1a described with reference to FIG. 3A. However, the unit pixel array UPA1a of FIG. 10 further illustrates a DTI formed between a first region A1 and a second region A2 and color filters in the first region A1.

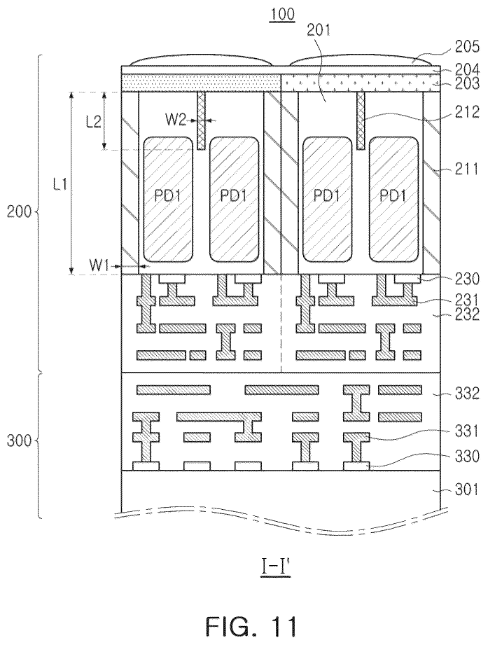

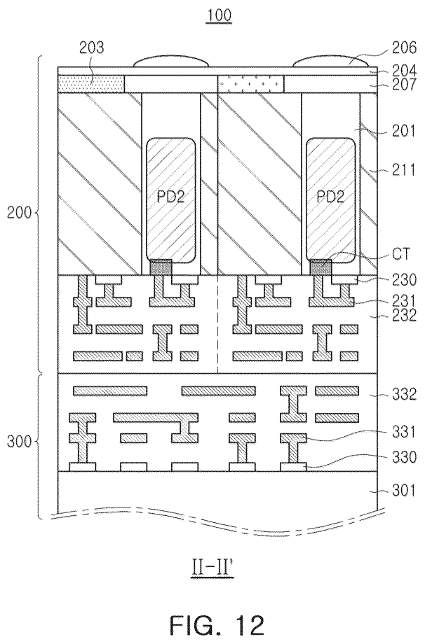

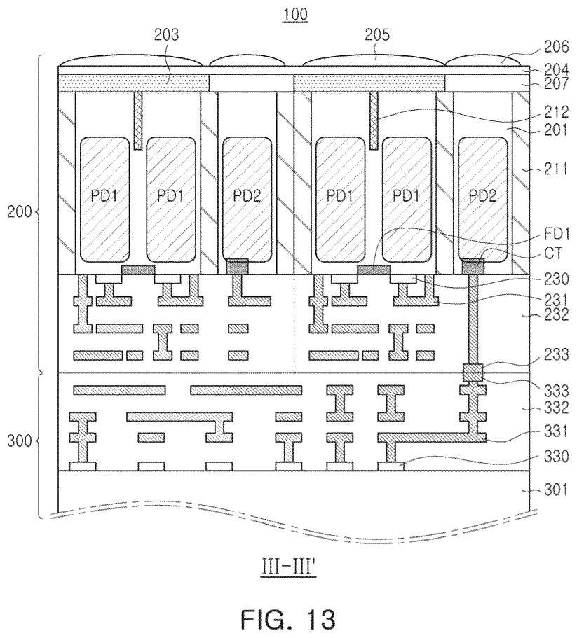

FIG. 11 is a cross-sectional view taken along line I-I′ of FIG. 10, FIG. 12 is a cross-sectional view taken along line II-II′ of FIG. 10, and FIG. 13 is a cross-sectional view taken along line III-III+ of FIG. 10.

Referring to FIGS. 11 to 13, the image sensor 100 may include an upper semiconductor chip 200, an intermediate semiconductor chip 300, and a lower semiconductor chip 400, as described with reference to FIG. 9. However, in FIGS. 11 to 13, the lower semiconductor chip 400 is omitted.

In the image sensor 100 according to an example embodiment of the disclosure, pixel circuits may be in lower portions of a plurality of photodiodes PD1 disposed in the first regions A1 and a plurality of photodiodes PD2 disposed in the second regions A2.

For example, a first pixel circuit may be disposed on a first surface of a first substrate 201. The first pixel circuit may include a plurality of first elements 230, first interconnection patterns 231 connected to the plurality of first elements 230, and a first insulating layer 232 covering the plurality of first elements 230 and first interconnection patterns 231.

The first pixel circuit may include a first floating diffusion node FD1. For example, the image sensing pixels PX1 included in the first region A1 described in FIG. 10 may share one first floating diffusion node.

The first floating diffusion node FD1 may be disposed near a pixel internal separator 212. For example, the first floating diffusion node FD1 may be in a position in which the first floating diffusion node FD1 overlaps the pixel internal separator 212 in a direction, perpendicular to a first surface of the first substrate 201. The plurality of first elements 230 adjacent to the first floating diffusion node FD1 may correspond to a plurality of first transfer transistors. Gates of the plurality of first transfer transistors may have a vertical structure in which at least a partial region of the gates (of the plurality of first transfer transistors) is buried in the substrate 201, and charges generated in the photodiode PD1 may move to the first floating diffusion node FD1 through the transfer transistors.

Each of the image sensing pixels PX1 may include a color filter 203, a light transmitting layer 204, and a microlens 205 disposed on a second surface opposite to the first surface of the first substrate 201. For example, each of the image sensing pixels PX1 may include a first microlens 205 disposed on an upper portion of the plurality of photodiodes PD1. Light of a wavelength component transmitted by the color filter 203, among the light passing through the first microlens 205 may be incident on the photodiodes PD1 in a lower portion the first microlens 205.

Referring to FIG. 11, a pixel separator 211 may have a first width W1 and a first length L1, and the pixel internal separator 212 may have a second width W2 and a second length L2. For example, the second width W2 of the pixel internal separator 212 may be narrower than the first width W1, and accordingly, the pixel separator 211 and the pixel internal separator 212 may be formed simultaneously in one process. However, the disclosure is not limited thereto, and according to an example embodiment, the first width W1 and the second width W2 may be the same.

In some embodiments, the first length L1 may be longer than the second length L2. However, the disclosure is not limited thereto, and the first length L1 and the second length L2 may each have various values. In an embodiment, the pixel separator 211 may completely penetrate from the first surface to the second surface of the first substrate 201.

In an example embodiment, the pixel internal separator 212 may have a length smaller than the plurality of photodiodes PD1 in the first direction. Accordingly, charges may move between the plurality of photodiodes PD1 with the pixel internal separator 212 interposed therebetween. For example, when the charges are excessively generated in one of the plurality of photodiodes PD1, saturation of the photodiode PD1 may be prevented by moving the charges.

The second pixel circuit may be disposed on the first surface of the second substrate 301 of the intermediate semiconductor chip 300. The second pixel circuit may include a plurality of second elements 330, second interconnection patterns 331 connected to the plurality of second elements 330, and a second insulating layer 332 covering the plurality of second elements 330 and the second interconnection patterns 331.

The upper semiconductor chip 200 may include a contact CT for connecting one or more photodiodes PD2 to the event sensing pixel circuit. Charges generated by the photodiode PD2 may move to the second pixel circuit through the contact CT.

The contact CT may penetrate through a region of the first substrate 201 in which the photodiode PD2 is formed. The insulating layer 332 may include a first signal pad 233 for electrically connecting circuit elements in a main region of the upper semiconductor chip 200 and a main region of the intermediate semiconductor chip 300. The contact CT may be connected to the first signal pad 233 through the first interconnection pattern 231.

The event sensing pixel PX2 may include a light transmitting layer and a second microlens 206 disposed on the second surface of the first substrate 201. For example, the event sensing pixel PX2 may include second microlenses 206 disposed on upper portions of each of the second photodiodes PD2. The light passing through the second microlens 206 may be incident on the photodiode PD2 in a lower portion of the second microlens 206.

In an example embodiment, the event sensing pixel PX2 may not include a color filter. For example, in an upper portion of the photodiode PD2, the light transmitting layer 207 having the same thickness as that of the color filter 203 disposed on an upper portion of the first photodiode PD1 may be disposed.

According to an example embodiment of the disclosure, the upper semiconductor chip 200 and the intermediate semiconductor chip 300 may be bonded through Chip-to-Chip (C2C) bonding. That is, the insulating layer 232 of the upper semiconductor chip 200 may be in contact with the insulating layer 332 of the intermediate semiconductor chip 300, and the signal pad 233 of the upper semiconductor chip 200 may be in contact with the signal pad 333 of the intermediate semiconductor chip 300. The second photodiodes PD2 may be electrically connected to the event sensing pixel circuit formed on the intermediate semiconductor chip 300 through the signal pads 233 and 333.

In FIGS. 11 to 13, a case in which the upper semiconductor chip 200 and the intermediate semiconductor chip 300 are bonded by the C2C bonding has described as an example, but the disclosure is not limited thereto. For example, the upper semiconductor chip 200 and the intermediate semiconductor chip 300 may be bonded by direct bonding.

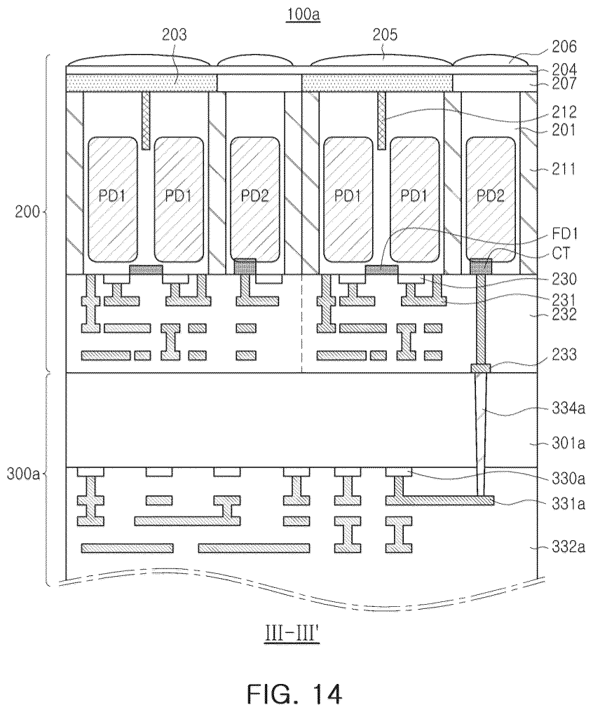

FIG. 14 illustrates a cross-sectional view taken along line III-III' in FIG. 10 when the upper semiconductor chip 200 and the intermediate semiconductor chip 300 are bonded by the direct bonding. In FIG. 14, the lower semiconductor chip 400 as described with reference to FIG. 9 is omitted.

A semiconductor device 100a of FIG. 14 may include an upper semiconductor chip 200 and an intermediate semiconductor chip 300a. The upper semiconductor chip 200 and the intermediate semiconductor chip 300a in FIG. 14 may have a similar structure to the upper semiconductor chip 200 and the intermediate semiconductor chip 300 described with reference to FIGS. 11 to 13. For example, a second substrate 301a, a plurality of second elements 330a, second interconnection patterns 331a, and a second insulating layer 332a of the intermediate semiconductor chip 300a may have a structure similar to that of the second substrate 301, the second element 330, the second interconnection patterns 331, and the second insulating layer 332 described with reference to FIGS. 11 to 13.

However, the intermediate semiconductor chip 300a of FIG. 14 may be bonded to the upper semiconductor chip 200 through the direct bonding, unlike the intermediate semiconductor chip 300 of FIGS. 11 to 13. That is, the insulating layer 232 of the upper semiconductor chip 200 and the second substrate 301a of the intermediate semiconductor chip 300a may be bonded to each other. The intermediate semiconductor chip 300a may include a through-via 334a penetrating through the second substrate 301a and penetrating through at least a portion of the insulating layer 332a so as to connect a photodiode PD2 to a event sensing pixel circuit. The through-via 334a may be in contact with the pad 233 of the upper semiconductor chip 200 and the interconnection pattern 331a.

In the examples of FIGS. 3A to 14, an example embodiment of the disclosure has been described using an example in which four photodiodes PD2 disposed in the second regions A2 are connected to one event sensing pixel circuit and included in one event sensing pixel PX2. However, the disclosure is not limited thereto. For example, when an area occupied by one second pixel is less than or equal to a sum of the first region A1 and the second region A2, one second pixel circuit may be electrically connected to one photodiode PD2, and may be disposed to overlap one first region A1.

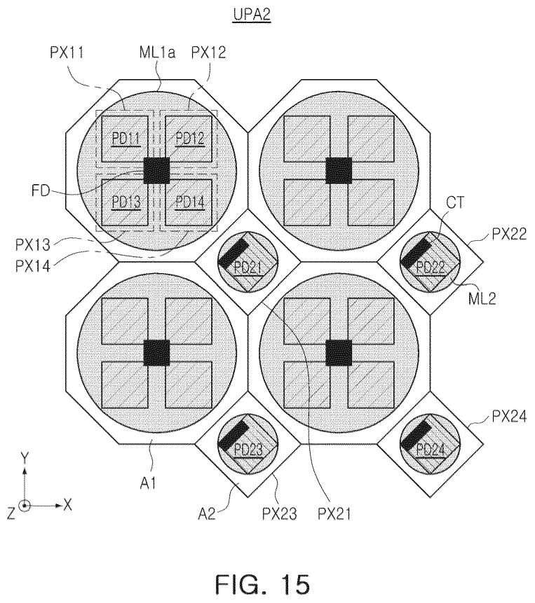

FIG. 15 is a plan view of pixels included in an image sensor according to an example embodiment of the disclosure.

An upper surface of a unit pixel array UPA2 in FIG. 15 may have the same structure as an upper surface of the unit pixel array UPA1a described with reference to FIG. 3A. However, in the unit pixel array UPA2 of FIG. 15, each of the plurality of photodiodes PD21 to PD24 may be included in one event sensing pixel. For example, the unit pixel array UPA2 may include four event sensing pixels PX21 to PX24.

According to an example embodiment of the disclosure, a event sensing pixel circuit of the event sensing pixel PX21 to PX24 may overlap a image sensing pixel circuit of the image sensing pixel group PG1 in the vertical direction (Z-direction). For example, the photodiodes PD11 to PD14, the photodiodes PD21 to PD24, and the first pixel circuits of the image sensing pixels may be included in the upper semiconductor chip. In some embodiments, in the intermediate semiconductor chip, each of the second pixel circuits of the event sensing pixels may be included in the second region A2 and the first region A1 adjacent to the second region A2.

The disclosure is not limited to a case in which image sensing pixels disposed on one first region A1 includes four photodiodes PD1. For example, the image sensing pixels may include one photodiode PD1, or may include nine photodiodes PD1, or may include a various number of photodiodes in one first region A1.

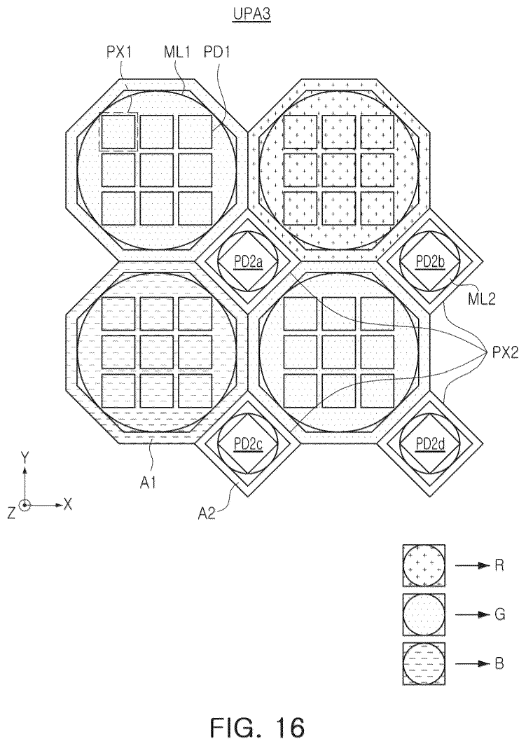

FIG. 16 is a plan view of pixels included in an image sensor according to an example embodiment of the disclosure.

An upper surface of a unit pixel array UPA3 of FIG. 16 may have a structure similar to that of the upper surface of the unit pixel array UPA1a described with reference to FIG. 3A. However, the unit pixel array UPA3 in FIG. 16 may include nine photodiodes PD1 arranged in a 3×3 shape in the first direction (X-direction) and the second direction (Y-direction) in one first region A1. The photodiodes PD1 included in one first region A1 may be included in image sensing pixels.

In the example of FIG. 16, the unit pixel array UPA3 may include a event sensing pixel PX2 including second photodiodes PD2a to PD2d included in four second regions A2. However, the present invention is not limited thereto. As a first example, the unit pixel array UPA3 may include four event sensing pixels PX2 comprised of one photodiode PD2 included in one second region A2. As a second example, the unit pixel array UPA3 may include nine first regions A1 and nine second regions A2, each of which is arranged in a 3×3 shape, and may include one event sensing pixel PX2 comprised of photodiodes PD2 included in the nine second regions A2.

According to an example embodiment of the disclosure, the image sensing pixels may have a split photodiode structure. The image sensing pixels having the split photodiode structure may include a small photodiode having a small light-receiving area, and a large photodiode having a larger light-receiving area than the small photodiode.

For example, the large photodiode may mainly generate image signals in low illuminance sections. The large photodiode may operate in a high conversion gain (HCG) mode in the lowest illuminance section, and may operate in a low conversion gain (LCG) mode in general low illuminance sections. The small photodiode may operate in high illuminance sections by lengthening the exposure time.

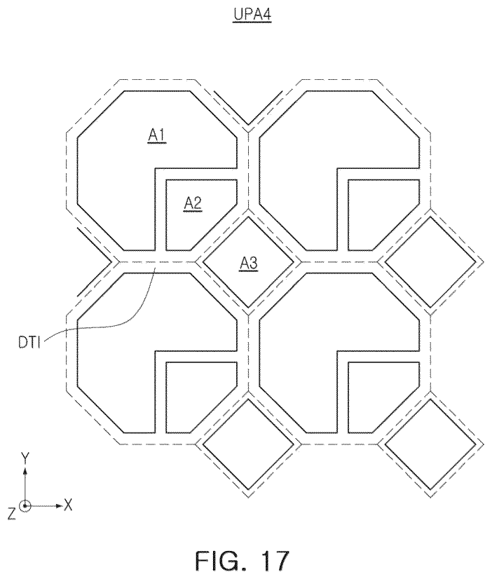

Hereinafter, referring to FIGS. 17 to 20, examples of structures that an image sensor according to an example embodiment of the disclosure may have when the image sensing pixels PX1 has the split photodiode structure are described.

FIGS. 17 to 19 are plan views of pixels included in an image sensor according to an example embodiment of the disclosure

Referring to FIG. 17, a unit pixel array UPA4 may include a plurality of first regions A1, a plurality of second regions A2, and a plurality of third regions A3. Each of the plurality of first regions A1, the plurality of second regions A2 and the plurality of third regions A3 may be in the first direction (X-direction) and the second direction (Y-direction) in parallel with an upper surface of a substrate and intersecting each other.

Specifically, the unit pixel array UPA4 may include a plurality of octagonal regions and a plurality of third regions A3. Each of the plurality of octagonal regions may have an octagonal shape including two first edges extending in the first direction (X-direction), two second edges extending in the second direction (Y-direction), and four third edges. In some embodiments, each of the plurality of third regions A3 may have a rectangular shape.

Each of the plurality of octagonal regions may adjoin at least one octagonal region in at least one of the first edges and at least one of the second edges. In some embodiments, each of the plurality of third regions A3 may be disposed between the plurality of octagonal regions. For example, each of the plurality of octagonal regions may adjoin at least one third region A3 in at least one of the third edges.

Each of the plurality of octagonal regions may include a first region A1 and a second region A2. In an example embodiment, an area of the first region A1 may be larger than an area of the second region A2. For example, the first region A1 may be in contact with three edges of the four third edges, and the second region A2 may be in contact with one third edge of the four third edges.

The deep trench isolation DTI may be formed in boundaries between the plurality of first regions A1, the plurality of second regions A2, and the plurality of third regions A3.

According to an example embodiment of the disclosure, each of the plurality of first regions A1 may include a large photodiode, and each of the plurality of second regions A2 may include a small photodiode. The large photodiode and the small photodiode each may be included in each of a plurality of image sensing pixels. In some embodiments, the plurality of third regions A3 may include photodiodes included in event sensing pixels.

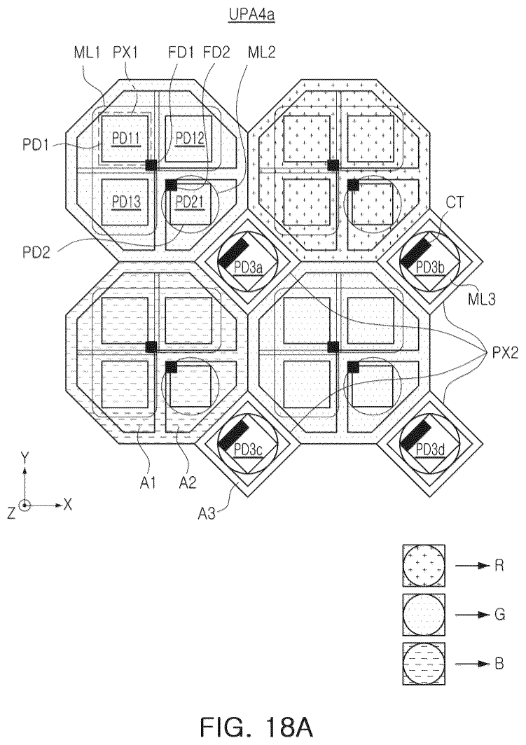

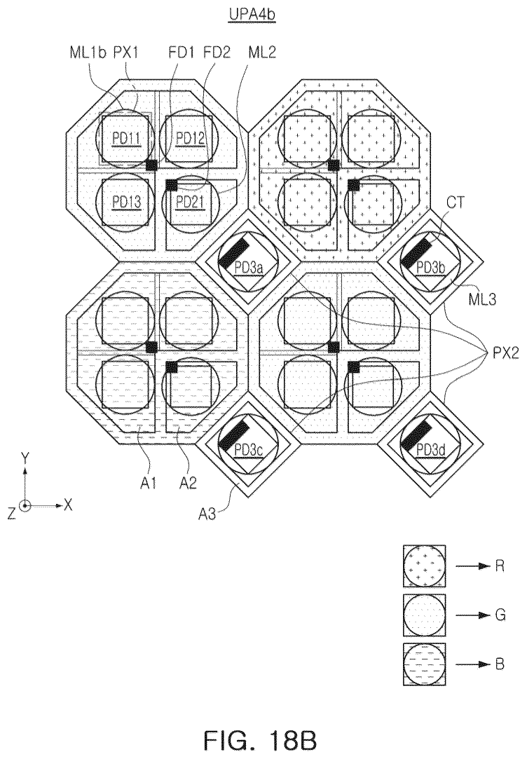

Referring to FIGS. 18A and 18B, unit pixel arrays UPA4a and UPA4b may include a plurality of image sensing pixels PX1 and one or more event sensing pixels PX2. The unit pixel arrays UPA4a and UPA4b may correspond to the unit pixel array UPA4 described with reference to FIG. 17.

Each of the first regions A1 may include one or more photodiodes PD11, PD12 and PD13 (PD1). In some embodiments, each of the second regions A2 may include one or more photodiodes PD21 (PD2). The sum of light-receiving areas of the photodiodes PD1 may be larger than a light-receiving area of the photodiode PD2. The sum of the photodiodes PD1 may be collectively referred to as a large photodiode, and the photodiode PD2 may be referred to as a small photodiode. A first region A1 and a second region A2 share a first pixel circuit. That is, the image sensing pixels PX1 may have a split photodiode structure.

Each of the first regions A1 may include one or more first floating diffusion nodes FD1. For example, the photodiodes PD1 included in one first region A1 may share one first floating diffusion node FD1. Each of the second regions A2 may include a second floating diffusion node FD2.

The first region A1 and the second region A2 included in one octagonal region may include a plurality of image sensing pixels sharing one first pixel circuit. The image sensing pixels PX1 may generate an image signal using at least portions of charges accumulated in the first floating diffusion node FD1 and charges accumulated in the second floating diffusion node FD2.

Each of the third regions A3 may include one or more third photodiodes. In the examples of FIGS. 18A and 18B, each of the third regions A3 may include one photodiode PD3a to PD3d. In an example embodiment, the photodiodes PD3 included in the plurality of third regions A3 included in the unit pixel arrays UPA4a and UPA4b may be included in one event sensing pixel PX2. Each of the third regions A3 may include a contact CT for transferring the charges generated in the photodiode PD3a to PD3d to the event sensing pixel PX2.

In the unit pixel array UPA4, microlenses included in upper portions of the first to third regions A1 to A3 may have various sizes and shapes.

In the example of FIG. 18A, the first region A1 may include one first microlens ML1 disposed on upper portions of the three first photodiodes PD1. In some embodiments, the second region A2 may include one second microlens ML2 in an upper portion of one photodiode PD2, and the third region A3 may include one third microlens ML3 in an upper portion of one photodiode PD3.

In the example of FIG. 18B, the first region A1 may include three first microlenses ML1b disposed on each of the three photodiodes PD1.

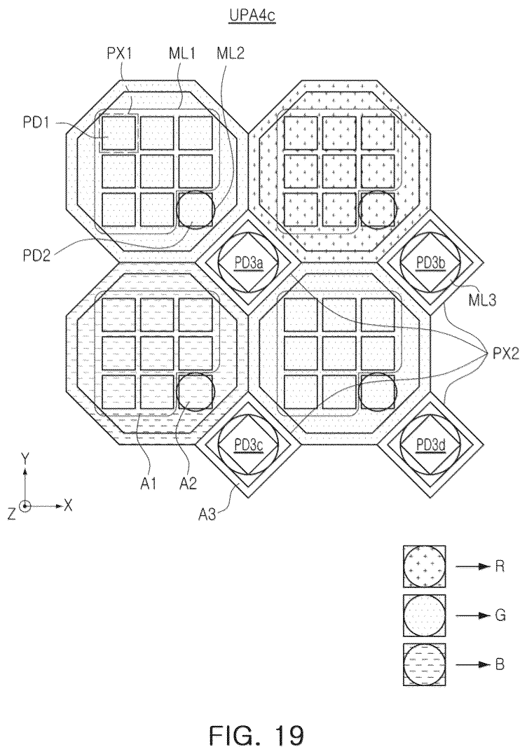

Referring to FIG. 19, a unit pixel array UPA4c may have a structure similar to that of the unit pixel array UPA4a of FIG. 18A. However, in the unit pixel array UPA4c of FIG. 19, one first region A1 may include eight photodiodes PD1. In one octagonal region, eight photodiodes PD1 and one photodiode PD2 may be arranged in a 3×3 shape.

The photodiodes PD1 and photodiodes PD2 in one octagonal region may share one first pixel circuit. The sum of light-receiving areas of the eight photodiodes PD1 may be greater than the sum of the light-receiving areas of the photodiodes PD2.

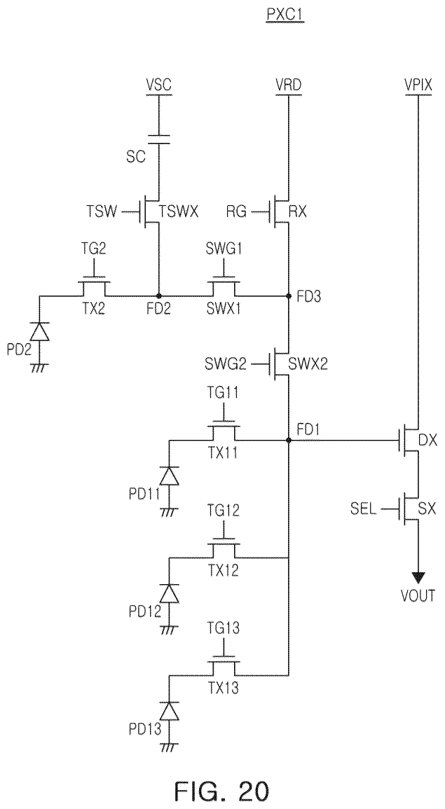

The event sensing pixel PX2 described with reference to FIGS. 18A, 18B and 19 may include the second pixel circuit, as described with reference to FIG. 8B. However, a first pixel circuit included in the image sensing pixels PG1 described with reference to FIGS. 18A, 18B and 19 may be different from the first pixel circuit described with reference to FIG. 8A. Hereinafter, a circuit structure of the first pixel group PG1 having a split photodiode structure will be described with reference to FIG. 20.

FIG. 20 is a circuit diagram illustrating a pixel circuit of an image sensor according to an example embodiment of the disclosure.

Referring to FIG. 20, a first pixel circuit PXC1 may output an electrical signal using charges generated by a plurality of photodiodes PD11 to PD13 included in one first area A1 and a photodiode PD2 included in one second area A2. An operation of active elements included in the image sensing pixel circuit may be controlled by the first logic circuit 20 included in the image sensor 1 described with reference to FIG. 1.

The first pixel circuit PXC1 may include a reset transistor RX, a plurality of first transfer transistors TX11, TX12 and TX13, a second transfer transistor TX2, a storage capacitor SC, a first switch transistor SWX1, a second switch transistor SWX2, a driving transistor DX, and a selection transistor SX.

Each of the plurality of photodiodes PD11 to PD13 may be connected to a first floating diffusion node FD1 through a plurality of first transfer transistors TX1. The plurality of photodiodes PD11 to PD13 may share the first floating diffusion node FD1. In some embodiments, the photodiode PD2 may be connected to a second floating diffusion node FD2 through the second transfer transistor TX2.

The storage capacitor SC may be an element for storing charges generated by the photodiode PD2. The storage capacitor SC may be implemented as a metal-insulator-metal (MIM) capacitor or an active capacitor. In an embodiment, a second power voltage VSC connected to the storage capacitor SC may be a value smaller than a first power supply voltage VDD of an entire pixel circuit. However, this is only an example and is not limited thereto, and the first power supply voltage VDD and the second power supply voltage VSC may be the same.

The storage capacitor SC may store charges in response to the amount of charges generated in the photodiode PD2 and an operation of the second transfer transistor TX2. The first switch transistor SWX1 may be connected between the storage capacitor SC and a third floating diffusion node FD3, and the charges of the storage capacitor SC may move to the third floating diffusion node FD3 by an on/off operation of the first switch transistor SWX1.

In an embodiment, the second switch transistor SWX2 may be connected between the third floating diffusion node FD3 and the first floating diffusion node FD1. That is, the third floating diffusion node FD3 may be connected to the reset transistor RX1, the first switch transistor SWX1, and the second switch transistor SWX2. The charges accumulated in the third floating diffusion node FD3 may move to the first floating diffusion node FD1 in response to an operation of the second switch transistor SWX2.

In an example embodiment illustrated in FIG. 20, the plurality of photodiodes PD1 and the plurality of photodiodes PD2 may share a column line Col. Accordingly, while a image sensing pixel voltage corresponding to the charges of the plurality of photodiodes PD11 to PD13 is output to the column line Col, the photodiode PD2 may be separated from the column line Col. For example, while the first pixel voltage is output to the column line Col, when at least one of the first switch transistor SWX1 and the second switch transistor SWX2 is turned off, the second photodiode PD2 may be separated from the column line Col. In order to generate the first pixel voltage using the charges of the plurality of first photodiodes PD1 and output the first pixel voltage to the column line Col, a first transfer transistor TX1 may be turned on so that charges generated in the photodiode PD1 may be accumulated in the first floating diffusion node FD1.

Similarly, while a second pixel voltage corresponding to the charge of the photodiode PD2 is output to the column line Col, the plurality of photodiodes PD11 to PD13 may be separated from the column line Col. For example, while the second pixel voltage is output to the column line Col, the first transfer transistor TX1 may be turned off so that the plurality of photodiodes PD11 to PD13 may be separated from the column line Col. In order to generate the second pixel voltage and output the second pixel voltage to the column line Col, the first switch transistor SWX1 and the second switch transistor SWX2 may be turned on so that the third floating diffusion node FD3 and the first floating diffusion node FD1 may be connected to each other. The charges generated in the photodiode PD2 and stored in the storage capacitor SC may be accumulated in the first floating diffusion node FD1, the second floating diffusion node FD2 and the third floating diffusion node FD3 and may be converted to voltage by the driving transistor DX.

An image sensor in which the image sensing pixel group PG1 has a split photodiode structure may have various structures in addition to the structures described with reference to FIGS. 17 to 19.

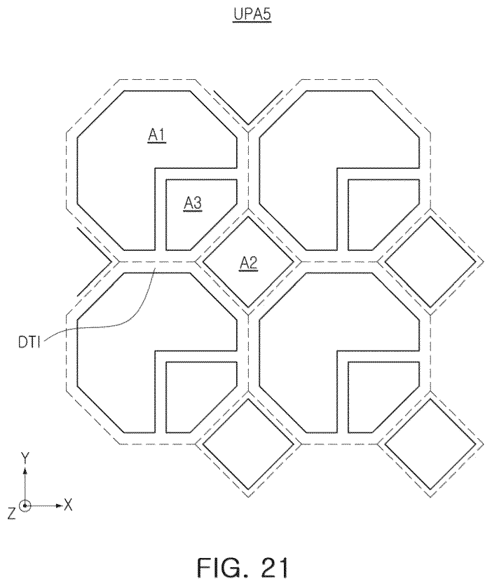

FIGS. 21 to 23 are plan views of pixels included in an image sensor according to an example embodiment of the disclosure.

Referring to FIG. 21, a unit pixel array UPA5 may include a plurality of first regions A1, a plurality of second regions A2, and a plurality of third regions A3. The unit pixel array UPA5 in FIG. 21 may have regions having a similar shape to the unit pixel array UPA4 described with reference to FIG. 17. However, the unit pixel array UPA5 may have a structure in which shapes and positions of the second regions A2 and the third regions A3 in the unit pixel array UPA4 are changed.

For example, each of the unit pixel array UPA5 may include a plurality of octagonal regions adjoining two first edges extending in the first direction (X-direction), two second edges extending in the second direction (Y-direction), and four third edges. Each of the plurality of octagonal regions may adjoin to at least one of the plurality of octagonal regions in at least one of the first edges and at least one of the second edges. Each of the plurality of octagonal regions may include a first region A1 and a third region A3.

The plurality of second regions A2 may be disposed between the plurality of octagonal regions. For example, at least one of the third edges of the plurality of octagonal regions may adjoin at least one of the plurality of second regions A2.

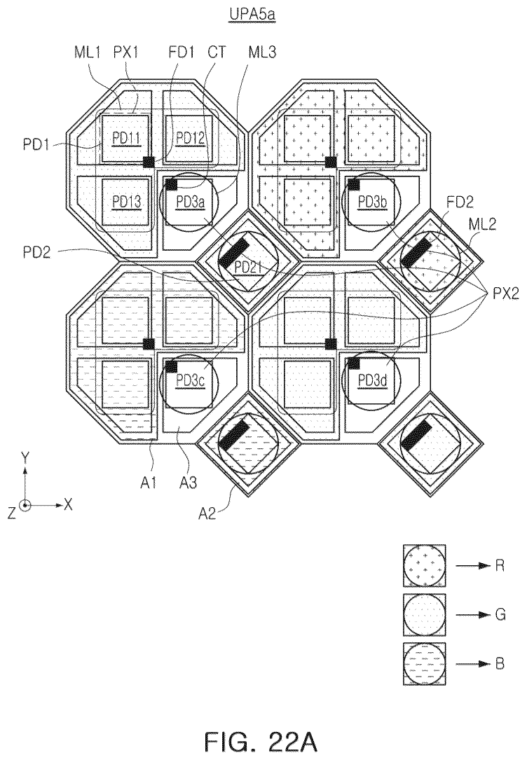

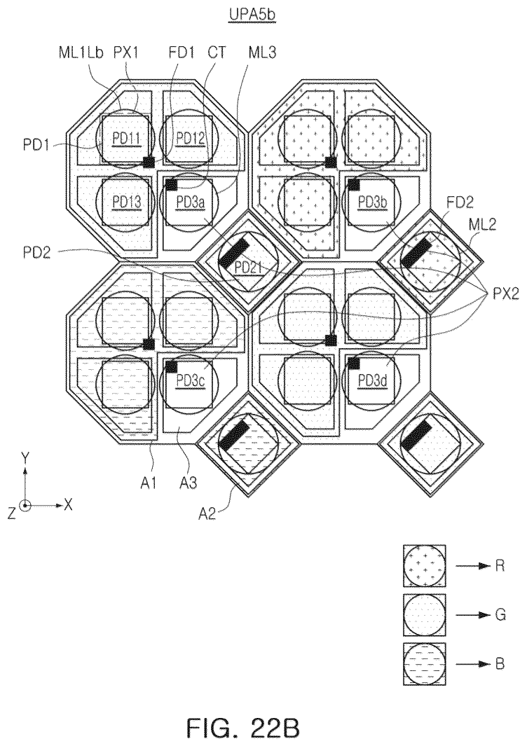

Referring to FIGS. 22A and 22B, unit pixel arrays UPA5a and UPA5b may include a plurality of image sensing pixel PX1 and one or more event sensing pixels PX2. The unit pixel arrays UPA5a and UPA5b may correspond to the unit pixel array UPA5 described with reference to FIG. 21.

Each of the first regions A1 may include one or more photodiodes PD11 to PD13 (PD1). In some embodiments, each of the second regions A2 may include one or more photodiodes PD21 (PD2). The sum of the light-receiving areas of the photodiodes PD1 may be larger than the light-receiving area of the photodiode PD2.

In an example embodiment, one first region A1 and one second region A2 spaced apart from each other with one third region A3 interposed therebetween may share one first pixel circuit. A color filter transmitting the same color may be in the first region A1 and the second region A2 which sharing one first pixel circuit.

Each of the third regions A3 may include one photodiode PD3a to PD3d. In an example embodiment, the third photodiodes PD3 included in the plurality of third regions A3 included in the unit pixel arrays UPA4a and UPA4b may be included in one event sensing pixel PX2.

In the unit pixel array UPA5, microlenses included in upper portions of the first to third regions A1 to A3 may have various sizes and shapes.

In the example of FIG. 22A, the first region A1 may include one first microlens ML1 in upper portions of the three photodiodes PD1. In some embodiments, the second region A2 may include one second microlens ML2 disposed on an upper portion of one photodiode PD2, and the third region A3 may include one third microlens ML3 disposed on an upper portion of the photodiode PD3.

In the example of FIG. 22B, the first region A1 may include three first microlenses ML1b disposed on upper portions of each of the three photodiodes PD1.

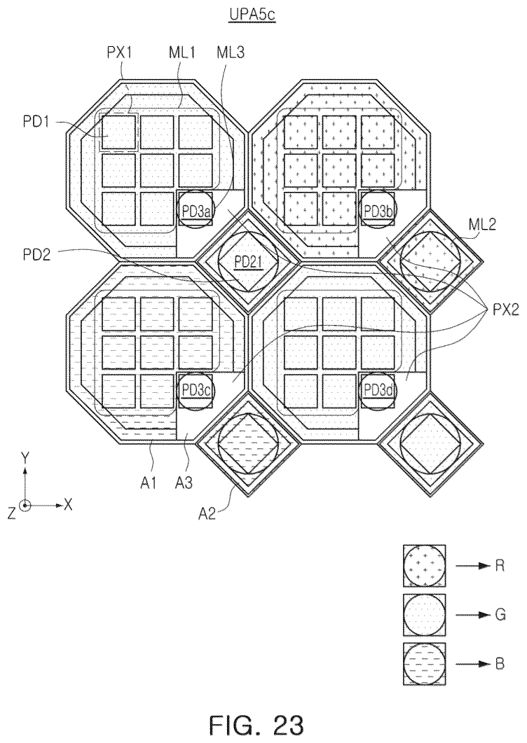

Referring to FIG. 23, a unit pixel array UPA5c may have a structure similar to the unit pixel array UPA5a of FIG. 21A. However, the unit pixel array UPA5c of FIG. 23 may include eight photodiodes PD1. In one octagonal region, eight first photodiodes PD1 and one photodiode PD3 may be arranged in a 3×3 shape.

One first region A1 and one second region A2 spaced apart from each other with one third region A3 interposed therebetween may share one first pixel circuit. The sum of light-receiving areas of eight photodiodes PD1 may be larger than the sum of the light-receiving areas of the photodiode PD2.

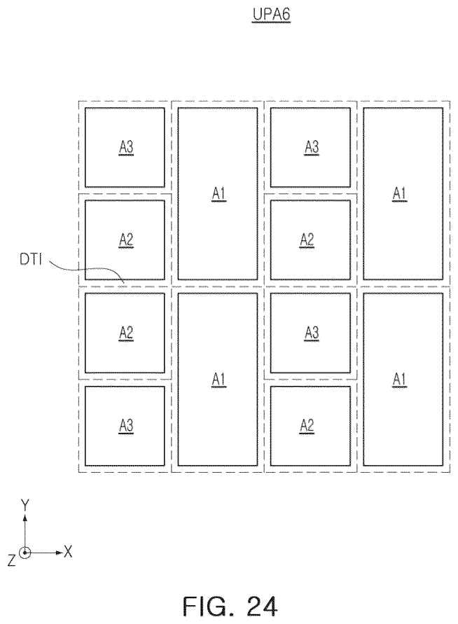

FIGS. 24 to 26 are plan views of pixels in an image sensor according to an example embodiment of the disclosure.

Referring to FIG. 24, a unit pixel array UPA6 may include a plurality of first regions A1, a plurality of second regions A2, and a plurality of third regions A3. The unit pixel array UPA6 may include a plurality of rectangular regions. Each of the plurality of rectangular regions may include one first region A1, one second region A2 and one third region A3.

In the example of FIG. 24, the first region A1 may be adjacent to the second region A2 and the third region A3 in the first direction (X-direction), and the second region A2 and the third region A3 may be adjacent to each other in the second direction (Y-direction). The plurality of third regions A3 may be spaced apart from each other in the first direction (X-direction) and the second direction (Y-direction).

A deep trench isolation DTI may be formed in boundaries between the first regions A1, the second regions A2, and the third regions A3.

According to an example embodiment of the disclosure, each of the plurality of first regions A1 may include a large photodiode, and each of the plurality of second regions A2 may include a small photodiode. The large photodiode and the small photodiode may sharing one first pixel circuit. In some embodiments, the plurality of third regions A3 may include photodiodes included in event sensing pixels.

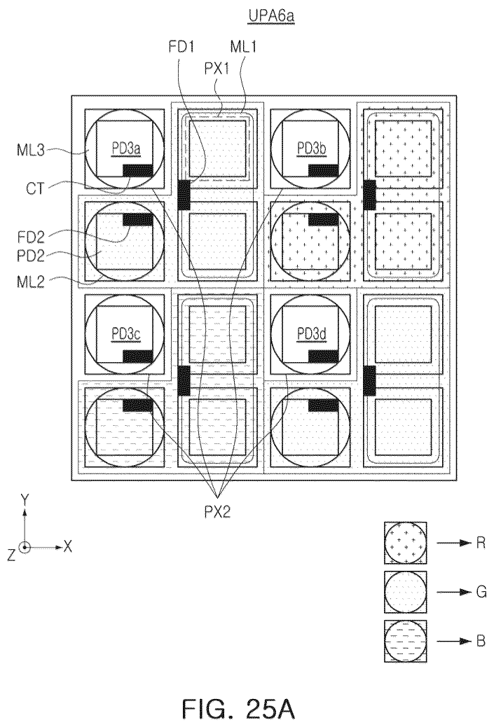

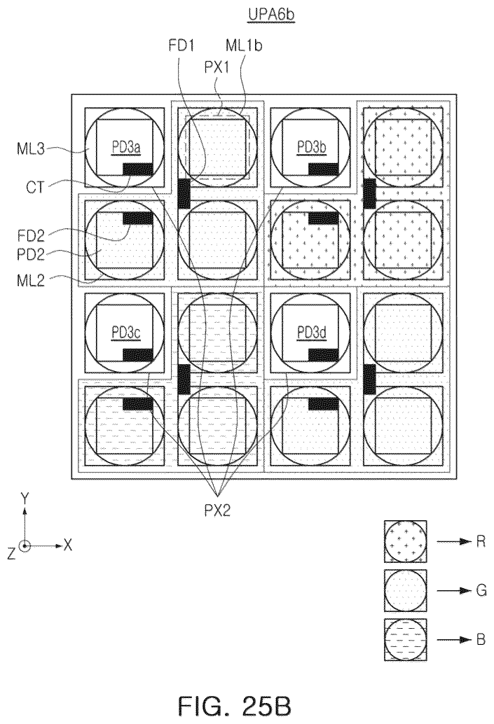

Referring to FIGS. 25A and 25B, unit pixel arrays UPA6a and UPA6b may include a plurality of image sensing pixels PX1 and one or more event sensing pixels PX2. The unit pixel arrays UPA6a and UPA6b may correspond to the unit pixel array UPA6 described with reference to FIG. 24.

In the examples of FIGS. 25A and 25B, each of the first regions A1 may include two photodiodes PD1, each of the second regions A2 may include one photodiode PD2, and each of the third regions A3 may include one photodiode PD3a to PD3d.

Similarly to what was described with reference to FIGS. 18A, 18B, 22A and 22B, the photodiodes PD1 and photodiodes PD2 included in one rectangular region may share one first pixel circuit. Image sensing pixels sharing one first pixel circuit may include a color filter transmitting the same color. In some embodiments, the photodiodes PD3 included in the plurality of third regions A3 included in the unit pixel arrays UPA6a and UPA6b may be included in one event sensing pixel PX2.

In the unit pixel array UPA6, microlenses included in upper portions of the first to third regions A1 to A3 may have various sizes and shapes.

In the example of FIG. 25A, the first region A1 may include one first microlens ML1 disposed on upper portions of the two photodiodes PD1. In some embodiments, the second region A2 may include one second microlens ML2 disposed on an upper portion of one photodiode PD2, and the third region A3 may include one third microlens ML3 disposed on an upper portion of one photodiode PD3.

In the example of FIG. 25B, the first region A1 may include two first microlenses ML1b disposed on upper portions of each of the two first photodiodes PD1.

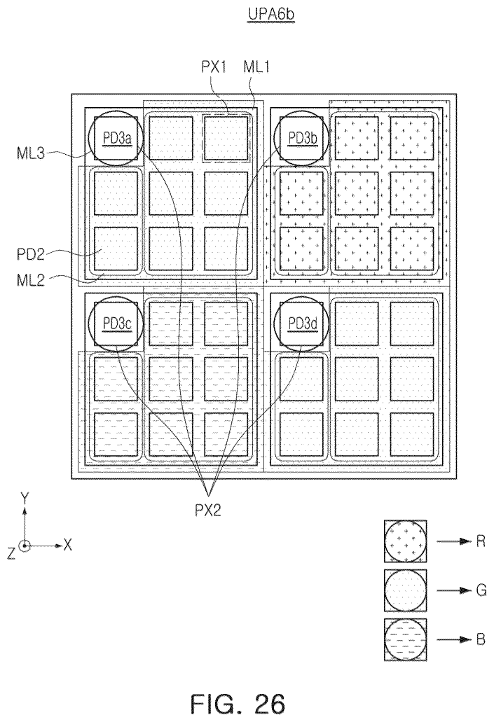

Referring to FIG. 26, a unit pixel array UPA6c may have a structure similar to that of the unit pixel array UPA6a of FIG. 25A. However, in the unit pixel array UPA6c of FIG. 26, one first region A1 may include six photodiodes PD1, and one second region A2 may include two photodiodes PD2. In one rectangular region, the photodiodes PD1, the photodiodes PD2, and the photodiode PD3 may be arranged in a 3×3 shape.

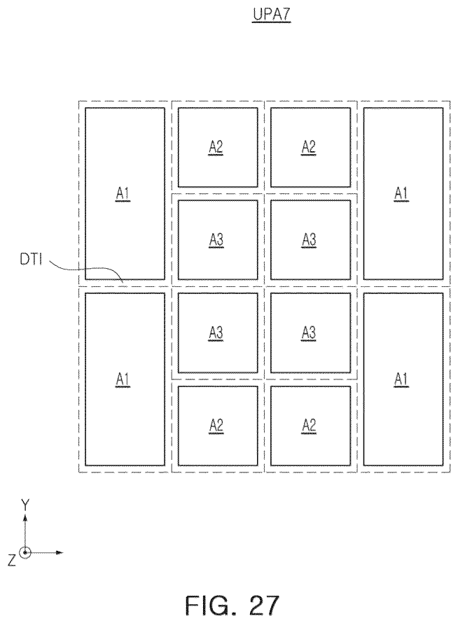

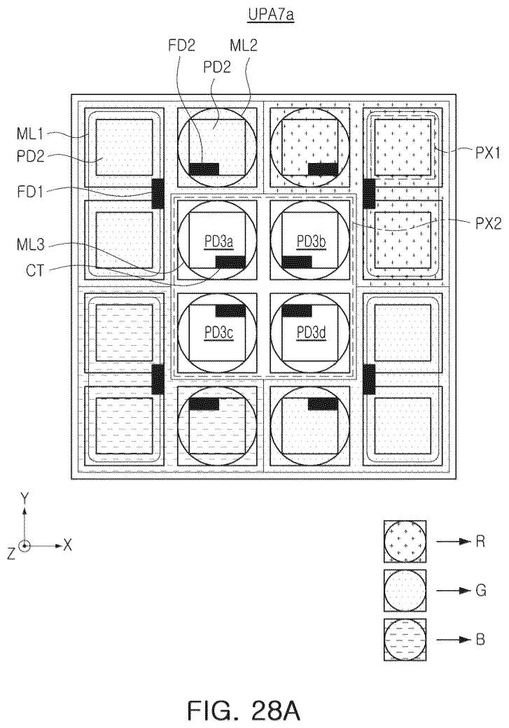

FIGS. 27 to 29 are plan views of pixels included in an image sensor according to an example embodiment of the disclosure

Referring to FIG. 27, a unit pixel array UPA7 may include a plurality of first regions A1, a plurality of second regions A2, and a plurality of third regions A3. The unit pixel array UPA7 may include a plurality of rectangular regions. Each of the plurality of rectangular regions may include one first region A1, one second region A2, and one third region A3.

Unlike the unit pixel array UPA6 described in FIG. 24, relative positions of the first region A1, the second region A2 and the third region A3 in one rectangular region of the unit pixel array UPA7 in FIG. 27 may be from each other. For example, in adjacent rectangular regions in the first direction (X-direction) and the second direction (Y-direction) of the unit pixel array UPA6, the third regions A3 may be adjacent to each other.

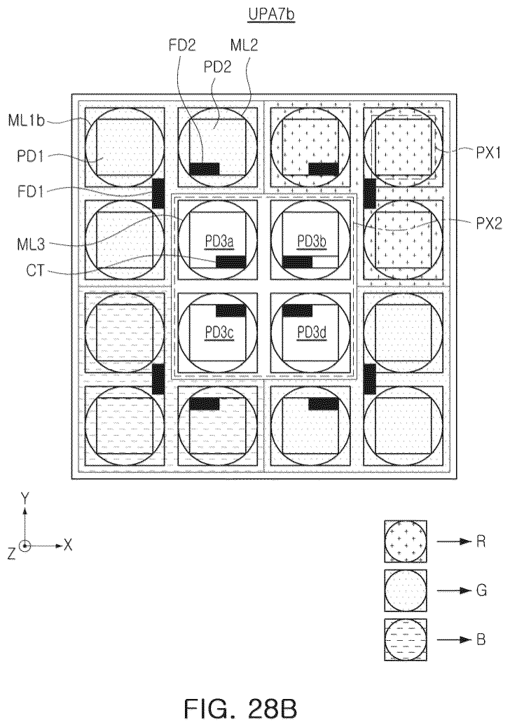

Referring to FIGS. 28A and 28B, unit pixel arrays UPA7a and UPA7b may include a plurality of image sensing pixels PX1 and one or more event sensing pixels PX2. The unit pixel arrays UPA7a and UPA7b may correspond to the unit pixel array UPA7 described with reference to FIG. 27.

Similarly to what is described with reference to FIGS. 25A and 25B, the photodiodes PD1 and the photodiodes PD2 included in one rectangular region may share one first pixel circuit. Image sensing pixels which sharing one first pixel circuit may include a color filter transmitting the same color. In some embodiments, the third photodiodes PD3 included in the plurality of third regions A3 included in the unit pixel arrays UPA7a and UPA7b may be included in one event sensing pixel PX2.

In the unit pixel array UPA7, microlenses included in upper portions of the first to third regions A1 to A3 may have various sizes and shapes.

In the example of FIG. 28A, the first region A1 may include one first microlens ML1 disposed on upper portions of the two photodiodes PD1. In some embodiments, the second region A2 may include one second microlens ML2 disposed on an upper portion of one photodiode PD2, and the third region A3 may include one third microlens ML3 disposed on an upper portion of one photodiode PD3a to PD3d.

In the example of FIG. 28B, the first region A1 may include two first microlenses ML1b disposed on upper portions of each of the two first photodiodes PD1.

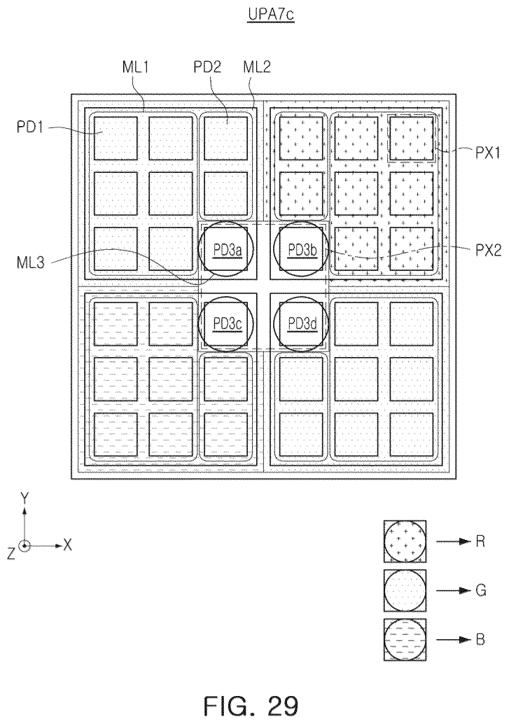

Referring to FIG. 29, a unit pixel array UPA7c may have a structure similar to that of the unit pixel array UPA7a of FIG. 28A. However, in the unit pixel array UPA7c of FIG. 29, one first region A1 may include six photodiodes PD1, and one second region A2 may include two photodiodes PD2. In one rectangular region, the first photodiodes PD1, photodiodes PD2, and photodiodes PD3 may be arranged in a 3×3 shape.

Examples of image sensors having various structures according to example embodiments of the disclosure have been described with reference to FIGS. 17 to 29. Hereinafter, an example of a vertical structure that an image sensor may have by including a lower semiconductor chip will be described.

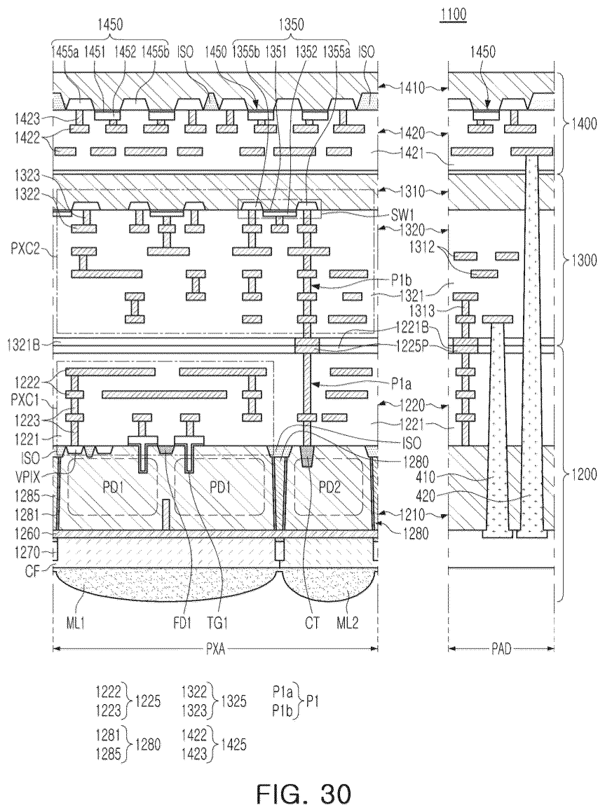

FIG. 30 is a side cross-sectional view illustrating an image sensor according to an example embodiment of the disclosure, which illustrates the cutout of the main region and the peripheral region.

An image sensor 1100 may include a first semiconductor chip 1200, a second semiconductor chip 1300, and a third semiconductor chip 1400. The first semiconductor chip 1200, the second semiconductor chip 1300 and the third semiconductor chip 1400 may correspond to the upper semiconductor chip 200, the intermediate semiconductor chip 300, and the lower semiconductor chip 400 described with reference to FIG. 9. In each of the first semiconductor chip 1200, the second semiconductor chip 1300 and the third semiconductor chip 1400, a main region MAIN and a peripheral region PERI may be defined.

The first semiconductor chip 1200 may include a first semiconductor substrate 1210 and a first interconnection structure 1220 disposed on the first semiconductor substrate 1210.

The first semiconductor substrate 1210 may be a silicon substrate or a semiconductor substrate such as silicon germanium. A surface on which semiconductor elements are formed in the first semiconductor substrate 1210 may be referred to as an upper surface or front side, and a side opposite to the upper surface of the first semiconductor substrate 1210 may be referred to as a lower surface or a back side.

The first semiconductor substrate 1210 may include a plurality of photodiodes PD1 and PD2 and a pixel separation structure 1280. In an example embodiment, a plurality of photodiodes PD1 may share a first pixel circuit PXC1, and a photodiode PD2 may connected to a second pixel circuit PXC2. The lower surface of the first semiconductor substrate 1210 may be a light-receiving surface on which light is incident.

The pixel separation structure 1280 may be disposed between a plurality of pixels arranged in a matrix shape to define the plurality of pixels. In an example embodiment, the pixel separation structure 1280 may physically and electrically separate the photodiode PD1 and the photodiode PD2. The pixel separation structure 1280 may have an FDTI structure penetrating through the semiconductor substrate 1210 from the upper surface of the semiconductor substrate 1210 to the lower surface of the semiconductor substrate 1210. A deep trench for the pixel separation structure 1280 may be formed in the semiconductor substrate 1210, and the pixel separation structure 1280 may include an insulating layer 1281 conformally formed on an internal surface of the trench, and a conductive layer 1285 filling the trench on the insulating layer 1281. For example, the insulating layer 1281 may include silicon oxide, silicon nitride, silicon oxynitride, hafnium oxide, aluminum oxide, and tantalum oxide. The conductive layer 1285 may include at least one of doped polysilicon, a metal, metal silicide, metal nitride, or a metal-containing film.

On the upper surface of the first semiconductor substrate 1210, semiconductor elements included in the image sensing pixel circuit as described with reference to FIG. 8A may be disposed. A device isolating pattern ISO may be formed in the first semiconductor substrate 1201 to define an active region in which first semiconductor elements are to be formed. For example, the device isolating pattern ISO may be formed by filling an insulating material in a shallow trench formed by patterning the first semiconductor substrate 1210.

The first semiconductor elements may include some of the elements included in the first pixel circuit, and may include transistors having a gate electrode, a gate insulating film, and source/drain regions.

The first semiconductor elements may include transistors such as a first transfer transistor TX1, a reset transistor RX, a driving transistor DX, and a selection transistor SX as described with reference to FIG. 8A.

At least a portion of the gate electrode of the first transfer transistor TX1 may extend in a vertical direction and may be buried in the first semiconductor substrate 1210. A first floating diffusion node FD1 may be connected to one end of the first transfer transistor TX1. When the first transfer transistor TX1 is turned on, the charges generated by the photodiode PD1 may be stored in the first floating diffusion node FD1.

The first interconnection structure 1220 on the upper surface of the first semiconductor substrate 1210 may include a first insulating layer 1221 and a first interconnection layer 1225 in the first insulating layer 1221. The first interconnection layer 1225 may be connected to the first semiconductor elements, and thus, may be included in the image sensing pixel circuit. The first interconnection layer 1225 may include a plurality of interconnection lines 1222 on a plurality of levels in the first insulating layer 1221 and an interconnection via 1223 connected to the plurality of interconnection lines 1222. For example, the first interconnection layer 1225 may include copper or copper alloys.

The second semiconductor chip 1300 may include a second interconnection structure 1320 on the first interconnection structure 1220 and having a capacitor 1380, and a second semiconductor substrate 1310 disposed on the second interconnection structure 1320. According to an example embodiment of the disclosure, the event sensing pixel circuit may be formed in the second semiconductor chip 1300.

A second semiconductor chip 1300 may be on the first semiconductor chip 1200. The first semiconductor chip and the second semiconductor chip may be bonded so that the first interconnection structure 1220 and the second interconnection structure 1320 face each other.

Second semiconductor elements included in the event sensing pixel circuit as described with reference to FIG. 8B may be disposed on an upper surface of the second semiconductor substrate 1310. The second semiconductor element 1350 may include some of the elements included in the event sensing pixel circuit, and may include transistors having a gate electrode 1352, a gate insulating film 1351, and source/drain regions 1355a and 1355b.

Similarly to the first interconnection structure 1220, the second interconnection structure 1320 may include a second insulating layer 1321 and a second interconnection layer 1325 in the second insulating layer 1321. The second interconnection layer 1325 may include a plurality of interconnection lines 1322 and interconnection vias 1223.

According to an example embodiment of the disclosure, a photodiode PD2 formed in the first semiconductor substrate 1210 may be connected to the second pixel circuit formed in the second semiconductor chip 1300 through a first metal pad 1225P.

The first interconnection structure 1220 may include a first bonding insulating layer 1221B disposed on an uppermost portion of the first interconnection structure 1220 and a first metal pad 1225P connected to the first interconnection layer 1225 in the first bonding insulating layer 1221B. Similarly, the second interconnection structure 1320 may include a second bonding insulating layer 1321B in a lowermost portion of the second interconnection structure 1320 and a second metal pad 1325P in the second bonding insulating layer 1321B. The first metal pad 1225P may have an upper surface that is substantially flat with an upper surface of the first bonding insulating layer 1221B, and the second metal pad 1325P may have an upper surface that is substantially flat with an upper surface of the first bonding insulating layer 1211B.

The first metal pad 1225P and the second metal pad 1352P may be directly bonded to form metal-to-metal bonding, and the first bonding insulating layer 1221B and the second bonding insulating layer 1321B may be directly bonded to form dielectric-to-dielectric bonding. Such bonding may also be referred to as hybrid bonding.

The first interconnection layer 1225 and the second interconnection layer 1325 may be electrically connected by bonding between the first metal pad 1225P and the second metal pad 1352P. The bonding between the first metal pad 1225P and the second metal pad 1352P may be electrically connect in not only the peripheral region PERI but also the main region MAIN. FIG. 30 illustrates first paths P1a and P1b (P1) for electrically connecting the second pixel circuit and the second photodiode PD2.

In an embodiment, in the peripheral region PERI, a first through-via 1510 may be further included to electrically connect the first semiconductor chip 1200 and the second semiconductor chip 1300.

The third semiconductor chip 1400 may include a third interconnection structure 1420 disposed on the second semiconductor substrate 1310, and a third semiconductor substrate 1410 disposed on the third interconnection structure 1420 and having logic elements implemented therein. The third semiconductor chip 1400 may include logic circuits.

Similarly to the first interconnection structure 1220 and the second interconnection structure 1320, the third interconnection structure 1420 may include a third insulating layer 1421 and a third interconnection layer 1425 in the third insulating layer 1421. The third interconnection layer 1425 may include a plurality of interconnection lines 1422 and interconnection vias 1423.

Third semiconductor elements 1450 formed in an active region defined by the device isolating pattern ISO may be formed on a lower surface of the third semiconductor substrate 1410. The third semiconductor elements 1450 may include a logic circuit, for example, a first logic circuit 20 and a second logic circuit 30 as described with reference to FIG. 1.

In an example embodiment, the third semiconductor chip 1400 is illustrated as being electrically connected to the first semiconductor chip 1200 and the second semiconductor chip 1300 by a second through-via 1520, but similarly to the connection between the first semiconductor chip 1200 and the second semiconductor chip 1300, the connection between the second semiconductor chip 1300 and the third semiconductor chip 1400 may be implemented by bonding with a metal pad, similarly to the connection between the second semiconductor chip 1300 and the third semiconductor chip 1400, instead of or in parallel with the second through via 1520.

The disclosure is not limited to the above-described embodiments and the accompanying drawings but is defined by the appended claims. Therefore, those of ordinary skill in the art may make various replacements, modifications, or changes without departing from the scope of the disclosure defined by the appended claims, and these replacements, modifications, or changes should be construed as being included in the scope of the disclosure.

What is claimed is:

1. An image sensor comprising:
a first region disposed in a first direction and a second direction in parallel with an upper surface of a substrate, wherein the first direction and the second direction intersect each other;
a second region disposed in the first direction and the second direction;
a first photodiode in the first region;
a second photodiode in the second region;
an image sensing pixel circuit configured to generate a first electrical signal based on charges generated by the first photodiode;
an event sensing pixel circuit configured to generate a second electrical signal based on a change in an amount of charges generated by the second photodiode; and
a logic circuit electrically connected to the image sensing pixel circuit,
wherein the first region is disposed diagonally to the second region in a third direction, and
wherein the third direction is different from the first and second directions.

2. The image sensor of claim 1, wherein a light-receiving area of the first photodiode is greater than a light-receiving area of the second photodiode.

3. The image sensor of claim 1, wherein the first region has an octagonal shape including two first edges extending in the first direction, two second edges extending in the second direction, and four third edges, and
wherein the second region has a rectangular shape.

4. The image sensor of claim 1, wherein the first and second photodiodes are disposed in a first chip, and
wherein the event sensing pixel circuit is disposed in a second chip stacked on the first chip.

5. The image sensor of claim 4, wherein the logic circuit is disposed in a third chip stacked on the second chip, and
wherein the second chip is disposed between the first chip and the third chip.

6. The image sensor of claim 5, further comprising:
a third photodiode in the first region; and
a floating diffusion node,
wherein the first photodiode and the third photodiode are configured to share the floating diffusion region.

7. The image sensor of claim 5, further comprising:
a floating diffusion node;
a reset transistor configured to reset a voltage of the floating diffusion node; and
a transfer transistor configured to transfer the charges generated by the first photodiode to the floating diffusion node,
wherein the floating diffusion node, the reset transistor, and the transfer transistor are disposed in the first chip.

8. The image sensor of claim 7, wherein the first chip is connected to the second chip through a copper to copper bonding.

9. The image sensor of claim 8, further comprising:
a third photodiode in the first pixel; and
a microlens is disposed on the first and third photodiodes.

10. The image sensor of claim 8, wherein the first chip is connected to the third chip through a through-via.

11. The image sensor of claim 10, further comprising:
a third region disposed directly adjacent to the first region in the first direction; and
a third photodiode in the third region,
wherein a light-receiving area of the third photodiode is greater than the light-receiving area of the second photodiode.

12. The image sensor of claim 11, further comprising:
a first microlens on the first photodiode; and
a second microlens on the second photodiode,
wherein a width of the first microlens in the second direction is greater than a width of the second microlens in the second direction.

13. The image sensor of claim 9, further comprising:
a fourth photodiode in the first pixel; and
a fifth photodiode in the first pixel,
wherein the microlens is disposed on the first, third, fourth, and fifth photodiodes.

14. The image sensor of claim 11, further comprising:
a deep trench isolation between the first region and the second region, and
wherein the deep trench isolation is in contact with the upper surface of the substrate.

15. The image sensor of claim 14, wherein the deep trench isolation is in contact with a lower surface of the substrate, and
wherein the lower surface of the substrate is opposing the upper surface of the substrate.

16. The image sensor of claim 8, wherein the transfer transistor is extended into the substrate.

17. An image sensor comprising:
a substrate;
a first photodiode in a first region in the substrate;
a second photodiode in a second region in the substrate;
a third photodiode in a third region in the substrate;
a fourth photodiode in a fourth region in the substrate;
a transfer transistor;
a reset transistor; and
an event sensing pixel circuit configured to generate an electrical signal based on a change in an amount of charges generated by the second photodiode,
wherein the third region is disposed directly adjacent to the first region in a first direction in a plan view,
wherein the fourth region is disposed directly adjacent to the first region in a second direction perpendicular to the first direction in the plan view,
wherein the second region is directly disposed diagonally to the first region in a third direction different from the first and second directions in the plan view,
wherein a light-receiving area of each of the first, third, and fourth photodiodes is greater than a light-receiving area of the second photodiode, and
wherein the transfer transistor and the reset transistor are shared by the first photodiode.

18. The image sensor of claim 17, wherein the first to fourth photodiodes, the transfer transistor, and the reset transistor are disposed in a first chip,
wherein the event sensing pixel circuit is disposed in a second chip,
wherein the first chip is stacked on the second chip, and
wherein the first chip is connect to the second chip through a copper to copper bonding.

19. The image sensor of claim 17, further comprising:
a first microlens on the first photodiode; and
a second microlens on the second photodiode,
wherein a width of the first micolens in the first direction is greater than a width of the second microlens in the first direction.

20. An image sensor comprising:
a substrate comprising a first surface and a second surface opposing the first surface;
a first photodiode in a first region in the substrate;
a second photodiode in a second region in the substrate;
a first microlens on the first photodiode;
a second microlens on the second photodiode;
an image sensing pixel circuit configured to generate a first electrical signal based on charges generated in the first photodiode;
an event sensing pixel circuit configured to generate a second electrical signal based on a change in an amount of charges generated by the second photodiode;
a deep trench isolation between the first region and the second region; and
a circuit electrically connected to the image sensing pixel circuit,
wherein the first region is directly adjacent to the second region,
wherein the deep trench isolation is in contact with the first surface of the substrate and the second surface of the substrate, and
wherein a width of the first microlens in a first direction is greater than a width of the second microlens in the first direction in a plan view.
